(19) United States
(12) Patent Application Publication
(10) Pub. No.: US 2011/0076618 A1
(43) Pub. Date: Mar. 31, 2011

(54) LITHOGRAPHIC PRINTING PLATE PRECURSOR AND PLATE MAKING METHOD THEREOF

(76) Inventor: MAMORU KURAMOTO, SHIZUOKA (JP)

(21) Appl. No.: 12/893,369

(22) Filed: Sep. 29, 2010

(30) Foreign Application Priority Data
Sep. 30, 2009 (JP) P2009-228944

(51) Int. Cl. G03F 7/004; G03F 7/20

(52) U.S. Cl. 430/281.1; 430/270.1; 430/302

(57) ABSTRACT

A lithographic printing plate precursor includes an aluminum support subjected to a surface roughening treatment, and an image-recording layer, the image-recording layer contains an infrared absorbing agent, a radical polymerization initiator, a radical polymerizable compound and an inorganic particle which has, on a surface of the inorganic particle, an acrylic polymer as a graft chain and an unexposed area of the image-recording layer is capable of being removed with at least one of oily ink and dampening water.

### CROSS-REFERENCE TO RELATED APPLICATIONS

This application claims the benefit of Japanese Patent Application JP 2009-228944, filed Sep. 30, 2009, the entire content of which is hereby incorporated by reference, the same as if set forth at length.

### FIELD OF THE INVENTION

The present invention relates to a lithographic printing plate precursor and a plate making method thereof. More particularly, it relates to a lithographic printing plate precursor capable of being subjected to image recording with laser and capable of being subjected to on-press development and a plate making method thereof.

### BACKGROUND OF THE INVENTION

In general, a lithographic printing plate is composed of an oleophilic image area accepting ink and a hydrophilic non-image area accepting dampening water (fountain solution) in the process of printing. Lithographic printing is aprintingmethodutilizing the nature of water and oily ink to repel with each other and comprising rendering the oleophilic image area of the lithographic printing plate to an ink-receptive area and the hydrophilic non-image area thereof to a dampening water-receptive area (ink-unreceptive area), thereby making a difference in adherence of the ink on the surface of the lithographic printing plate, depositing the ink only to the image area, and then transferring the ink to a printing material, for example, paper.

In order to produce the lithographic printing plate, a lithographic printing plate precursor (PS plate) comprising a hydrophilic support having provided thereon an oleophilic photosensitive resin layer (image-recording layer) has heretofore been broadly used. Ordinarily, the lithographic printing plate is obtained by conducting plate making according to a method of exposing the lithographic printing plate precursor through an original, for example, a lith film, and then while leaving the image-recording layer corresponding to the image area, removing the unnecessary image-recording layer corresponding to the non-image area by dissolving with an alkaline developer or a developer containing an organic solvent thereby revealing the hydrophilic surface of support.

In the hitherto known plate making process of lithographic printing plate precursor, after exposure, the step of removing the unnecessary image-recording layer by dissolving, for example, with a developer is required. However, it is one of the subjects to save or simplify such an additional wet treatment described above. Particularly, since disposal of liquid wastes discharged accompanying the wet treatment has become a great concern throughout the field of industry in view of the consideration for global environment in recent years, the demand for the solution of the above-described subject has been increased more and more.

As one of simple plate making methods in response to the above-described requirement, a method referred to as on-press development has been proposed wherein a lithographic printing plate precursor having an image-recording layer capable of being removed in its unnecessary areas during a conventional printing process is used and after exposure, the unnecessary area of the image-recording layer is removed on a printing machine to prepare a lithographic printing plate.

Specific methods of the on-press development include, for example, a method of using a lithographic printing plate precursor having an image-recording layer that can be dissolved or dispersed in dampening water, an ink solvent or an emulsion of dampening water and ink, a method of mechanically removing an image-recording layer by contact with rollers or a blanket cylinder of a printing machine, and a method of lowering cohesion of an image-recording layer or adhesion between an image-recording layer and a support upon penetration of dampening water, ink solvent or the like and then mechanically removing the image-recording layer by contact with rollers or a blanket cylinder of a printing machine.

Further, as another method for simple development, a method referred to as gum development has been proposed wherein removal of the unnecessary area of the image-recording layer is performed with a gum solution, which has been used as a finisher conducting after conventional alkali development, without using a conventional highly alkaline developer.

In the invention, unless otherwise indicated particularly, the term “development processing step” means a step of using an apparatus (ordinarily, an automatic developing machine) other than a printing machine and removing an unexposed area in an image-recording layer of a lithographic printing plate precursor upon contact with liquid (ordinarily, an alkaline developer) thereby revealing a hydrophilic surface of support. The term “on-press development” means a method or a step of removing an unexposed area in an image-recording layer of a lithographic printing plate precursor upon contact with liquid (ordinarily, printing ink and/or dampening water) by using a printing machine thereby revealing a hydrophilic surface of support.

Further, of the “development processing step”, development using a gum solution as a developer is specifically referred to as “gum development”.

On the other hand, digitalized technique of electronically processing, accumulating and outputting image information using a computer has been popularized in recent years, and various new image-outputting systems responding to the digitalized technique have been put into practical use. Correspondingly, attention has been drawn to a computer-to-plate technique of carrying digitalized image information on highly converging radiation, for example, a laser beam and conducting scanning exposure of a lithographic printing plate precursor with the radiation thereby directly preparing a lithographic printing plate without using a lith film. Thus, it is one of the important technical subjects to obtain a lithographic printing plate precursor adaptable to the technique described above.

In the simplification of plate making operation as described above, a system using an image-recording layer capable of being handled in a bright room or under a yellow lump and a light source is preferable from the standpoint of workability.

As such a laser light source, a semiconductor laser emitting an infrared ray having a wavelength of 760 to 1,200 and a solid laser, for example, YAG laser, are extremely useful because those lasers having a large output and a small size are inexpensively available. An UV laser can also be used.

As the lithographic printing plate precursor of on-press development type capable of being subjected to image-recording with an infrared laser, for example, a lithographic printing plate precursor having provided on a hydrophilic support, an image-forming layer in which hydrophobic thermoplastic polymer particles are dispersed in a hydrophilic binder is described in Japanese Patent 2,938,397. It is described in Japanese Patent 2,938,397 that the lithographic printing plate precursor is exposed to an infrared laser to agglomerate the hydrophobic thermoplastic polymer particles by heat thereby forming an image and mounted on a plate cylinder of a printing machine to be able to carry out on-press development by supplying dampening water and/or ink.

Although the method of forming image by the agglomeration of fine particles only upon thermal fusion shows good on-press development property, it has a problem in that the image strength is extremely weak and printing durability is insufficient.

Further, a lithographic printing plate precursor having provided on a hydrophilic support, microcapsules containing a polymerizable compound encapsulated therein is described in JP-A-2001-277740 (the term “JP-A” as used herein means an “unexamined published Japanese patent application”) and JP-A-2001-277742.

Moreover, a lithographic printing plate precursor having provided on a support, a photosensitive layer (image-recording layer) containing an infrared absorbing agent, a radical polymerization initiator and a polymerizable compound is described in JP-A-2002-287334.

The methods using the polymerization reaction as described above have the feature that since the chemical bond density in the image area is high, the image strength is relatively good in comparison with the image area formed by the thermal fusion of hydrophobic thermoplastic polymer fine particles. From the practical standpoint, however, any of the on-press development property and printing durability is still insufficient.

Thus, it is proposed that an inorganic filler, for example, a silica particle or a surface-modified silica particle is incorporated into a photosensitive layer to increase the strength of the photosensitive layer and to reduce the contraction of the photosensitive layer so that the image strength is further increased thereby improving the printing durability as described in JP-A-11-143082 and JP-A-2006-317716.

However, the effect of improving developing property is small even when such an inorganic filler is incorporated into the photosensitive layer and since the surface-modified silica particles described in JP-A-11-143082 and JP-A-2006-317716 have high specific gravity, a problem causes in the production process in that the silica particles are precipitated when added to a solution for photosensitive layer.

### SUMMARY OF THE INVENTION

Therefore, an object of the present invention is to provide a novel filler which is excellent in affinity with an image-recording layer and reduces the self-contraction on crosslinking the image-recording layer and to provide a lithographic printing plate precursor which is excellent in on-press development property, stability of a coating solution and printing durability and a plate making method thereof.

The object of the present invention can be achieved by adding an inorganic fine particle, for example, a silica particle or mica, which has on its surface an acrylic polymer as a graft chain, to an image-recording layer. Specifically, the present invention includes the following items.

(1) A lithographic printing plate precursor comprising an aluminum support subjected to a surface roughening treatment and an image-recording layer which contains (A) an infrared absorbing agent, (B) a radical polymerization initiator, (C) a radical polymerizable compound and (D) an inorganic fine particle which has on its surface an acrylic polymer as a graft chain and an unexposed area of which is capable of being removed with at least any one of oily ink and dampening water.
(2) The lithographic printing plate precursor as described in (1) above, wherein the graft chain is represented by formula (A) shown below:

-L₁-S—P₁ Formula (A)

In formula (A), L₁ represents a connecting chain covalently bonded to the inorganic fine particle, and P₁ represents an acrylic polymer chain.

(3) The lithographic printing plate precursor as described in (1) or (2) above, wherein a surface of the inorganic fine particle is modified with the graft chain by a silane coupling reaction.
(4) The lithographic printing plate precursor as described in any one of (1) to (3) above, wherein the graft chain comprising the acrylic polymer has a repeating unit represented by formula (B) shown below:

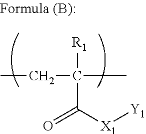

In formula (B), R₁ represents a hydrogen atom or a methyl group, X₁ represents an oxygen atom, —NH— or a single bond, Y₁ represents a hydrogen atom, a polyalkyleneoxy group, an alkyl group having from 1 to 4 carbon atoms, —N(R₂)(R₃) or an alkyl or aryl group having at least one group selected from —N(R₂)(R₃), —NHCOR₂, —COOR₂, —OR₂, —CN, —SO₃H and a salt thereof, R₂ and R₃ each independently represents a hydrogen atom or an alkyl group having from 1 to 12 carbon atoms or R₂ and R₃ may be combined with each other to form a ring. A number of the repeating units is from 10 to 1,000.

(5) The lithographic printing plate precursor as described in (4) above, wherein X₁ represents an oxygen atom or —NH—, and Y₁ represents a polyethyleneoxy group.
(6) The lithographic printing plate precursor as described in (5) above, wherein the graft chin comprising the acrylic polymer has a repeating unit represented by formula (C) shown below:

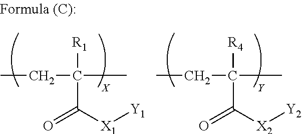

In formula (C), Y₁ represents a polyethyleneoxy group, Y₂ represents a substituent having an ethylenically unsaturated group, X₁ and X₂ each independently represents an oxygen atom or —NH—, R₁ and R₄ each independently represents a hydrogen atom or a methyl group, X and Y each represents a copolymerization molar ratio of the repeating unit, X is from 10 to 90 and Y is from 5 to 50.

(7) The lithographic printing plate precursor as described in any one of (1) to (6) above, wherein the inorganic fine particle is a silica fine particle.
(8) The lithographic printing plate precursor as described in (7) above, wherein an average particle size of the silica fine particle is from 20 to 500 nm.
(9) The lithographic printing plate precursor as described in any one of (1) to (7) above, wherein the inorganic fine particle is an inorganic stratiform compound.
(10) The lithographic printing plate precursor as described in any one of (1) to (9) above, wherein the image-recording layer further contains (E) a polymer compound having a polyalkyleneoxy group in its side chain.
(11) The lithographic printing plate precursor as described in any one of (1) to (10) above, wherein the radical polymerizable compound (C) in the image-recording layer has a polyalkyleneoxy group.
(12) A plate making method comprising after image exposure of the lithographic printing plate precursor as described in any one of (1) to (11) above, without undergoing a development processing step, removing an exposed area with at least any one of oily ink and dampening water on a printing machine to prepare a lithographic printing plate.

According to the present invention, a lithographic printing plate precursor of on-press development type which is excellent in on-press development property, stability of a coating solution and printing durability and a plate making method thereof can be provided.

### DETAILED DESCRIPTION OF THE INVENTION

### Lithographic Printing Plate Precursor

The lithographic printing plate precursor according to the invention comprises an image-recording layer and an aluminum support subjected to a surface roughening treatment and is capable of being subjected to on-press development by supplying at least any one of oily ink and dampening water and the image-recording layer contains an inorganic fine particle which has on its surface an acrylic polymer as a graft chain.

It is believed that by adding an inorganic fine particle, for example, a silica particle or mica to an image-recording layer, the strength of the image-recording layer is increased and the contraction of the image-recording layer is reduced thereby improving the printing durability and in addition, because the inorganic fine particle has on its surface a suitable acrylic polymer as a graft chain, the inorganic fine particle as a filler is excellent in affinity with the image-recording layer so that the inorganic fine particles are uniformly present in the image-recording layer without the formation of aggregation and dampening water can penetrate via the acrylic polymer thereby increasing the on-press development property.

Further, it is believed that since the inorganic fine particles have on their surfaces an acrylic polymer as a graft chain, the inorganic fine particles are stable in a coating solution due to the dispersion force between the acrylic polymer and a solvent of the coating solution and they do not precipitate in the coating solution.

### (Image-Recording Layer)

The image-recording layer for use in the invention is an image-recording layer capable of forming an image by supplying after imagewise exposure, at least any one of printing ink and dampening water on a printing machine to remove the unexposed area thereof.

The image formation mechanism according to the invention is an embodiment which contains (A) an infrared absorbing agent, (B) a radical polymerization initiator, (C) a radical polymerizable compound and (D) an inorganic fine particle which has on its surface an acrylic polymer as a graft chain and includes curing of the image area utilizing a radical polymerization reaction. Also, (E) a polymer compound having a polyalkyleneoxy group in its side chain may be incorporated into the image-recording layer of radical polymerization type.

Hereinafter, (D) an inorganic fine particle which has on its surface an acrylic polymer as a graft chain, (A) an infrared absorbing agent, (B) a radical polymerization initiator and (C) a radical polymerizable compound will be described in detail.

[(D) Inorganic Fine Particle which has on its Surface Acrylic Polymer as Graft Chain]

### [Inorganic Fine Particle]

The inorganic fine particle a surface of which is modified according to the invention is preferably a particle containing as the main component, an element selected from silicon, aluminum and iron. Among them, a particle containing silicon as the main component is preferred, a particle containing silicon dioxide (SiO₂) as the main component is more preferred, and a silica particle or a mica compound is most preferred.

The silica particle a surface of which is modified according to the invention is conventionally used in the field of art and contains silicon dioxide (SiO₂) as the main component. The silica particle has a particle size ordinarily from 1 nm to 10 μm, preferably from 10 to 500 nm, more preferably from 20 to 300 nm, as measured by a light scattering particle size distribution analyzer and has a variety of shape, for example, spherical, acicular, amorphous or necklace-like formed by linking of spherical particles. A silica sol in which the silica particles are stably dispersed in water is preferably used. The silica particles are commercially available and, for example, various types of colloidal silica are available under the trade name “SNOWTEX” from Nissan Chemical Industries, Ltd. As a spherical silica sol, for example, SNOWTEX XS (particle size: 4 to 6 nm), SNOWTEX S (particle size: 8 to 11 nm), SNOWTEX 20 (particle size: 10 to 20 nm), SNOWTEX XL (particle size: 40 to 60 nm), SNOWTEX YL (particle size: 50 to 80 nm), SNOWTEX ZL (particle size: 70 to 100 nm) or SNOWTEX MP-2040 (particle size: 200 nm) is preferably used. As a silica sol of acidic type formed by removing sodium salt on its surface, for example, SNOWTEX OXS or SNOWTEX OS is preferably used. As an acicular or amorphous silica sol, for example, SNOWTEX UP, SNOWTEX OUP, and FINE CATALOID F-120 available from Catalysts & Chemicals Industries Co., Ltd. are exemplified. As a necklace-like silica sol, for example, SNOWTEX PS-S (particle size: 80 to 120 nm), SNOWTEX PS-M (particle size: 80 to 150 nm) and as their acidic types, SNOWTEX PS-SO and SNOWTEX PS-MO are exemplified.

The silica particle includes a form, for example, of fumed silica, precipitated silica or colloidal silica. Among them, colloidal silica is preferably used.

The mica compound for use in the invention includes mica, for example, natural mica or synthetic mica.

Of the mica compounds for use in the invention, examples of the natural mica include muscovite, paragonite, phlogopite, biotite and lepidolite. Examples of the synthetic mica include non-swellable mica, for example, fluorphlogopite KMg₃(AlSi₃O₁₀)F₂ or potassium tetrasilic mica KMg_{2.5}(Si₄O₁₀)F₂, and swellable mica, for example, Na tetrasilic mica NaMg_{2.5} (Si₄O₁₀) F₂, Na or Li teniolite (Na, Li)Mg₂Li (Si₄O₁₀) F₂, or montmorillonite based Na or Li hectolite (Na, Li)_{1/8}Mg_{2/5}Li_{1/8}(Si₄O₁₀)F₂. Synthetic smectite is also useful.

Of the mica compounds, fluorine-based swellable mica is particularly useful in the invention. Specifically, the swellable synthetic mica has a stratiform structure comprising a unit crystal lattice layer having a thickness of approximately from 100 to 150 nm (10 to 15 angstroms), and metallic atom substitution in the lattices thereof is remarkably large in comparison with other clay minerals. As a result, the lattice layer results in lack of positive charge and to compensate it, a cation, for example, Na⁺, Ca²⁺ or Mg²⁺ is adsorbed between the lattice layers. The cation existing between the lattice layers is referred to as an exchangeable cation and is exchangeable with various cations. In particular, in the case where the cation between the lattice layers is Li⁺ or Na⁺, because of a small ionic radius, a bond between the stratiform crystal lattices is week, and the swellable mica greatly swells upon contact with water. When share is applied under such condition, the stratiform crystal lattices are easily cleaved to form a stable sol in water. The swellable synthetic mica has strongly such tendency and is useful in the invention. Particularly, the swellable synthetic mica is preferably used from the standpoint of ready availability of particles having uniform quality.

The shape of the mica compound for use in the invention is tabular and from the standpoint of adsorption to the inorganic fine particle, the thinner the thickness or the larger the plain size as long as smoothness of coated surface and transmission of actinic radiation are not damaged, the better. Therefore, an aspect ratio of the mica compound is ordinarily 20 or more, preferably 100 or more, and particularly preferably 200 or more. The aspect ratio is a ratio of major axis to thickness of particle and can be determined, for example, from a projection drawing of particle by a microphotography. The larger the aspect ratio, the greater the effect obtained.

As for the particle size of the mica compound for use in the invention, an average major axis is ordinarily from 0.3 to 20 μm, preferably from 0.5 to 10 μm, and particularly preferably from 1 to 5 μm. An average thickness of the mica compound is ordinarily 0.1 μm or less, preferably 0.05 μm or less, and particularly preferably 0.01 μm or less. Specifically, for example, with respect to the swellable synthetic mica which is the representative compound of the mica compounds, the thickness is approximately from 1 to 50 nm and the plain size (major axis) is approximately from 1 to 20 μm.

[Surface Modification of Inorganic Fine Particle with Acrylic Polymer Chain]

The surface modification of inorganic fine particle with an acrylic polymer chain is conducted by forming a covalent bond to the inorganic fine particle as shown in formula (A) below.

-L₁-S—P₁ Formula (A)

In formula (A), L₁ represents a connecting chain covalently bonded to the inorganic fine particle, and P₁ represents an acrylic polymer chain.

In particular, it is preferred that the inorganic particle and the acrylic polymer graft chain are bonded by a silane coupling reaction to conduct the surface modification.

The acrylic polymer graft chain containing a repeating unit having a structure represented by formula (B) shown below is preferred.

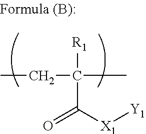

In formula (B), R₁ represents a hydrogen atom or a methyl group. X₁ represents an oxygen atom, —NH— or a single bond. Y₁ represents a hydrogen atom, a polyalkyleneoxy group, an alkyl group having from 1 to 4 carbon atoms, —N(R₂)(R₂) or an alkyl or aryl group having at least one group selected from —N(R₂)(R₂), —NHCOR₂, —COOR₂, —OR₂, —CN, —SO₃H and a salt thereof.

The alkyl group is preferably an alkyl group having from 1 to 4 carbon atoms and the aryl group is preferably an aryl group having from 6 to 10 carbon atoms.

R₂ and R₃ each independently represents a hydrogen atom or an alkyl group having from 1 to 12 carbon atoms or R₂ and R₃ may be combined with each other to form a ring. It is preferred that R₂ and R₃ each independently represents a hydrogen atom or a methyl group. A number of the repeating units is from 10 to 1,000, preferably from 30 to 500 and more preferably from 50 to 200.

Y₁ is preferably a polyalkyleneoxy group, a methyl group or an alkyl group having from 1 to 4 carbon atoms and having at least one group selected from —OH, —OCH₂, —SO₃H and a salt thereof.

The polyalkyleneoxy group is described in detail below. The alkylene moiety in the polyalkyleneoxy group is preferably —CH₂CH₂— or —(CH₂)₂—, and at least one of the hydrogen atoms therein may be substituted with an alkyl group.

The polyalkyleneoxy group is preferably a group represented by the following formula:

—(CHR₁₀₁CHR₁₀₂O)ₘ—R₁₀₃

In the above formula, R₁₀₁ and R₁₀₂ each independently represents a hydrogen atom or a substituent, R₁₀₃ represents a hydrogen atom or a substituent, and m represents a number of 2 to 50, preferably 2 to 25.

R₁₀₁ and R₁₀₂ each independently represents a hydrogen atom or a substituent. When R₁₀₁ or R₁₀₂ represents a substituent, the substituent preferably includes an alkyl group having from 1 to 40 carbon atoms (for example, a methyl group, an ethyl group, a propyl group, a butyl group, a pentyl group, a hexyl group, a heptyl group, an octyl group, a nonyl group, a decyl group, an isopropyl group, an isobutyl group, a sec-butyl group, a tert-butyl group, an isopentyl group, a neopentyl group, a 1-methylbutyl group, an isohexyl group, a 2-ethylhexyl group, a 2-methylhexyl group, a cyclopentyl group, a cyclohexyl group, a 1-adamantyl group, a 2-norbornyl group, a benzyl group and an allyl group).

R₁₀₁ and R₁₀₂ each independently represents preferably a hydrogen atom or an alkyl group having from 1 to 30 carbon atoms, more preferably a hydrogen atom or an alkyl group having from 1 to 20 carbon atoms, particularly preferably a hydrogen atom or a methyl group, and most preferably a hydrogen atom, which corresponds to a polyethyleneoxy group.

R₁₀₃ represents preferably a hydrogen atom, an alkyl group having from 1 to 40 carbon atoms, an aryl group having from 6 to 40 carbon atoms, a heterocyclic group, an alkylcarbonyl group, an arylcarbonyl group, a carbamoyl group, an N-alkylcarbamoyl group, an N-arylcarbamoyl group, an N,N-dialkylcarbamoyl group, an N,N-diarylcarbamoyl group or an N-alkyl-N-arylcarbamoyl group, and more preferably a hydrogen atom, an alkyl group having from 1 to 40 carbon atoms, an aryl group having from 6 to 40 carbon atoms, a heterocyclic group, an alkylcarbonyl group, an arylcarbonyl group, a carbamoyl group, an N-alkylcarbamoyl group, an N-arylcarbamoyl group, an N,N-dialkylcarbamoyl group, an N,N-diarylcarbamoyl group or an N-alkyl-N-arylcarbamoyl group.

R₁₀₃ is more preferably a hydrogen atom or an alkyl group having from 1 to 10 carbon atoms, and particularly preferably a hydrogen atom or a methyl group.

Moreover, an acrylic copolymer graft chain having a repeating unit represented by formula (C) shown below is preferred from the standpoint of more improving printing durability.

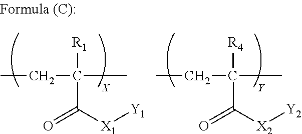

In formula (C), Y₁ represents a polyethyleneoxy group. Preferable examples of the polyethyleneoxy group are same as those described in formula (B) above. Y₂ represents a substituent having an ethylenically unsaturated group. X₁ and X₂ each independently represents an oxygen atom or —NH—. R₁ and R₄ each independently represents a hydrogen atom or a methyl group. X and Y each represents a copolymerization molar ratio of the repeating unit, X is from 10 to 90 and Y is from 5 to 50, and preferably, X is from 15 to 80 and Y is from 10 to 40. The polymer may further have other repeating unit(s) which is added by radical polymerization, but, in case the polymer is made by only the above two repeating units, it is preferable that X is from 60 to 80 and Y is from 20 to 40.

### [Method for Surface Modification]

For the surface modification of inorganic fine particle with an acrylic polymer chain, a first method is exemplified wherein a polymer having a functional group reacting with the inorganic fine particle at its one terminal is used and the functional group is subjected to a chemical reaction with a functional group on the surface of the inorganic fine particle to effect grafting.

The functional group reacting with the inorganic fine particle is not particularly restricted as long as it is capable of reacting with a functional group on the surface of the inorganic fine particle and includes, for example, a silane coupling group, e.g., an alkoxysilane, an isocyanate group, an amino group, a hydroxy group, a carboxyl group, a sulfonic acid group, a phosphoric acid group, an epoxy group, an allyl group, a methacryloyl group and an acryloyl group. A particularly useful compound as the polymer having a reactive functional group at its one terminal is an acrylic polymer having a trialkoxysilyl group at its one terminal.

A second method is a method wherein a compound having a polymerizable double bond is polymerized originating from the inorganic fine particle to form a graft polymer, and the method is ordinarily referred to as a surface graft polymerization method. The surface graft polymerization method is a method wherein an active species is generated on the surface of the inorganic fine particle by a method, for example, of plasma irradiation, light irradiation or heating and a compound having polymerizable double bond which is placed in contact with the inorganic fine particle is polymerized to be covalently bonded to the inorganic fine particle.

As the surface graft polymerization method for practicing the invention, any known method described in literatures can be used. For instance, as the surface graft polymerization method, a photo-graft polymerization method and a plasma irradiation graft polymerization method are described in Shin Kobunshi Jikken-Gaku 10 (New Polymer Experimentation 10), page 135, edited by Society of Polymer Science, Japan, published by Kyoritsu Shuppan Co., Ltd. An irradiation graft polymerization method using a radiation, for example, a γ ray or an electron beam is described in Kyuchaku Gijutu Binran (Manual for Adsorption Technique), page 203, page 695, supervised by Takeuchi, published by NTS Co., Ltd. (February 1999). As a specific procedure of the photo-graft polymerization method, methods described in JP-A-63-92658, JP-A-10-296895 and JP-A-11-119413 can be used. In the plasma irradiation graft polymerization method and the radiation irradiation graft polymerization method, methods described in the literatures above and Y. Ikeda, et al., Macromolecules, vol. 19, page 1804 (1986) can be applied.

### [Details of First Method]

In the surface modification of the inorganic fine particle, a compound used as a silane coupling agent can be preferably employed.

### (Polymer Compound Represented by Formula (1))

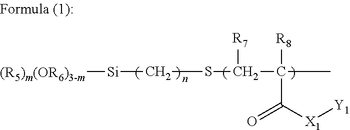

The polymer compound represented by formula (1) is a hydrophilic polymer having a silane coupling group at its one terminal and hereinafter it is appropriately referred to as a specific acrylic polymer.

In formula (1), m represents an integer of 0 to 2. R₈, R₆, R₇ and R₈ each independently represents a hydrogen atom or a hydrocarbon group having from 1 to 8 carbon atoms. The hydrocarbon group includes, for example, an alkyl group and an aryl group and is preferably a straight-chain, branched or cyclic alkyl group having 8 or less carbon atoms. Specific examples of the hydrocarbon group include a methyl group, an ethyl group, a propyl group, a butyl group, a pentyl group, a hexyl group, a heptyl group, an octyl group, an isopropyl group, an isobutyl group, a sec-butyl group, a tert-butyl group, an isopentyl group, a neopentyl group, a 1-methylbutyl group, an isohexyl group, a 2-ethylhexyl group, a 2-methylhexyl group and a cyclopentyl group.

R₅, R₆, R₇ and R₈ each preferably represents a hydrogen atom, a methyl group or an ethyl group from the standpoint of the effect and easiness of availability.

X₁ represents an oxygen atom, —NH— or a single bond. Y₁ represents a hydrogen atom, a polyalkyleneoxy group, an alkyl group having from 1 to 4 carbon atoms, —N(R₂)(R₃) or an alkyl or aryl group having at least one group selected from —N(R₂)(R₃), —NHCOR₂, —COOR₂, —OR₂, —CN, —SO₃H and a salt thereof.

The alkyl group is preferably an alkyl group having from 1 to 4 carbon atoms and the aryl group is preferably an aryl group having from 6 to 10 carbon atoms.

R₂ and R₃ each independently represents a hydrogen atom or an alkyl group having from 1 to 12 carbon atoms or R₂ and R₃ may be combined with each other to form a ring. When R₂ and R₃ may be combined with each other to form a ring, the ring formed may be a hetero ring containing a hetero atom, for example, an oxygen atom, a sulfur atom or a nitrogen atom. It is preferred that R₂ and R₃ each independently represents a hydrogen atom or a methyl group. A number of the repeating units is preferably from 10 to 1,000.

Y₁ is preferably a polyalkyleneoxy group, a methyl group or an alkyl group having from 1 to 4 carbon atoms and having at least one group selected from —OH, —OCH₃, —SO₃H and a salt thereof.

For Y₁, a hydroxyethyl group or a polyalkyleneoxy group is preferred, and a polyalkyleneoxy group is particularly preferred. The polyalkyleneoxy group has the same meaning as the polyalkyleneoxy group described in formula (B).

n represents a natural number of 2 to 20, and from the standpoint of the effect and easiness of availability, from 2 to 6 is preferred, and 3 is most preferred.

Specific examples of the monomer forming a repeating unit of a polymer skeleton of the specific acrylic polymer include methyl acrylate, ethyl acrylate, n- or iso-propyl acrylate, n-, iso-, sec- or tert-butyl acrylate, chloroethyl acrylate, 2-hydroxyethyl acrylate, 2-hydroxypropyl acrylate, 2-hydroxypentyl acrylate, allyl acrylate, trimethylolpropane monoacrylate, pentaerythritol monoacrylate, methoxybenzyl acrylate, hydroxybenzyl acrylate, hydroxyphenethyl acrylate, dihydroxyphenethyl acrylate, furfuryl acrylate, tetrahydrofurfuryl acrylate, hydroxyphenyl acrylate, sulfamoylphenyl acrylate, 2-(hydroxyphenylcarbonyloxy)ethyl acrylate, methyl methacrylate, ethyl methacrylate, n- or iso-propyl methacrylate, n-, iso-, sec- or tert-butyl methacrylate, chloroethyl methacrylate, 2-hydroxyethyl methacrylate, 2-hydroxypropyl methacrylate, 2-hydroxypentyl methacrylate, allyl methacrylate, trimethylolpropane monomethacrylate, pentaerythritol monomethacrylate, methoxybenzyl methacrylate, hydroxybenzyl methacrylate, hydroxyphenethyl methacrylate, dihydroxyphenethyl methacrylate, furfuryl methacrylate, tetrahydrofurfuryl methacrylate, hydroxyphenyl methacrylate, sulfamoylphenyl methacrylate, 2-(hydroxyphenylcarbonyloxy)ethyl methacrylate, acrylamide, methacrylamide, acrylamido-2-methylpropanesulfonic acid and methacrylamido-2-methylpropanesulfonic acid.

In order to improve the on-press development property and printing durability, the affinity of the polymer to water is important and the polymer which is water permeable and is insoluble in water is preferred. It is preferred that the polymer has in the side chain thereof, a polyalkyleneoxy group or an alkyl group having from 1 to 4 carbon atoms and having at least one group selected from —OH, —OCH₃, —SO₃H and a salt thereof.

A hydroxyethyl group or a polyalkyleneoxy group is more preferred, and a polyalkyleneoxy group is particularly preferred. The polyalkyleneoxy group has the same meaning as the polyalkyleneoxy group described in formula (B).

Moreover, in order to improve adhesion property to the image-recording layer, it is preferred that the polymer has an ethylenically unsaturated bond. The acrylic polymer having a polyethyleneoxy group and an ethylenically unsaturated bond is most preferred.

As the ethylenically unsaturated bond, an ethylenically unsaturated group, for example, a (meth)acryl group, a vinyl group or an allyl group is preferred. The ethylenically unsaturated group can be introduced into the polymer by a polymer reaction or copolymerization. For instance, a reaction between an acrylic polymer having a carboxyl group in its side chain and glycidyl methacrylate, a reaction between an acrylic polymer having an epoxy group and a carboxylic acid containing an ethylenically unsaturated group, for example, methacrylic acid or a reaction between an acrylic polymer having an isocyanate group and hydroxyethyl acrylate can be utilized.

Specifically, the acrylic copolymer chain having a repeating unit represented by formula (C) described above is preferred. The acrylic copolymer chain is used as the specific acrylic polymer shown below, for the surface modification of the inorganic fine particle.

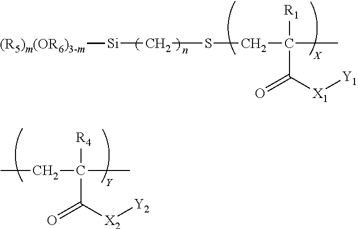

In the formula above, R₅, R₆, m and n have the same meanings as those defined in formula (1) above and R₁, R₄, X₁, Y₁, X₂, Y₂, X and Y have the same meanings as those defined in formula (C) above, respectively.

Specific examples (Compounds 1 to 13) of the specific acrylic polymer suitably used in the invention are set forth below, but the invention should not be construed as being limited thereto.

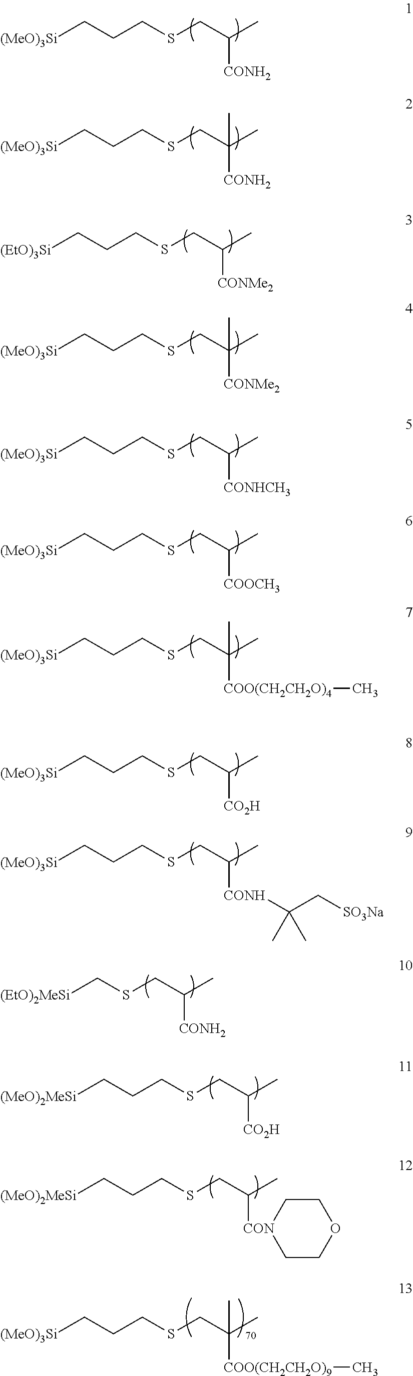

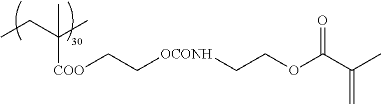

The specific acrylic polymer according to the invention can be synthesized by radical polymerization using a radical polymerizable monomer represented by formula (i) shown below and a silane coupling agent having chain transfer ability in the radical polymerization represented by formula (ii) shown below. Since the silane coupling agent represented by formula (ii) has the chain transfer ability, the polymer having a silane coupling group introduced into one terminal of the main chain thereof in the radical polymerization can be synthesized.

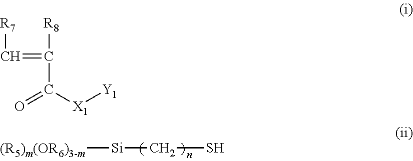

In formulae (i) and (ii), R₅ to R₈, X₁, Y₁, m and n have the same meanings as those defined in formula (1) above, respectively.

These compounds are commercially available and can also be easily synthesized.

Any heretofore known method can be used as the radical polymerization method for synthesizing the hydrophilic polymer represented by formula (1). Specifically, ordinary radical polymerization methods are described, for example, in Shin Kobunshi Jikken-Gaku 3 (New Polymer Experimentation 3), Kobunshi no Gousei to Hannou 1 (Synthesis and Reaction of Polymers 1), edited by Society of Polymer Science, Japan, published by Kyoritsu Shuppan Co., Ltd., Shin Jikken Kagaku Kouza 19 (Course of Experimental Chemistry 19), Kobunshi Kagaku (I) (Polymer Chemistry (I)), edited by The Chemical Society of Japan, published by Maruzen Co., Ltd, and Busshitu Kogaku Kouza (Course of Material Engineering), Kobunshi Gousei Kagaku (Synthetic Polymer Chemistry), published by Tokyo Denki University Press, and these methods can be utilized.

### [Details of Second Method]

The second method is specifically a method wherein a group which will form the starting point of polymerization is introduced on the surface of the inorganic fine particle utilizing a silane coupling reaction and then a graft chain is formed by polymerization of a monomer.

Specifically, a method is preferred wherein the surface of the inorganic fine particle is modified using a compound selected from γ-methacryloxypropylmethyldimethoxysilane, γ-methacryloxypropylmethyldiethoxysilane, γ-methacryloxypropyltrimethoxysilane, γ-methacryloxypropyltriisopropoxysilane, γ-methacryloxypropyltri-tert-butoxysilane, γ-mercaptopropylmethyldimethoxysilane, γ-mercaptopropylmethyldiethoxysilane, γ-mercaptopropyltrimethoxysilane, γ-mercaptopropyltriethoxysilane, γ-mercaptopropyltriisopropoxysilane and γ-mercaptopropyltri-tert-butoxysilane, as the silane coupling agent and then a polymer is provided, and a method is more preferred wherein the surface of the inorganic fine particle is modified using a compound selected from γ-mercaptopropylmethyldimethoxysilane, γ-mercaptopropylmethyldiethoxysilane, γ-mercaptopropyltrimethoxysilane, γ-mercaptopropyltriethoxysilane, γ-mercaptopropyltriisopropoxysilane and γ-mercaptopropyltri-tert-butoxysilane and then a polymer is provided by radical polymerization.

The repeating unit derived from an acrylic monomer present in the acrylic graft chain is same as that described in the first method. For example, the repeating unit is formed from the monomer described in the first method.

In order to improve the on-press development property and stability of coating solution, the affinity of the polymer to water is important and the polymer which is water permeable and is insoluble in water is preferred. It is preferred that the polymer has in the side chain thereof, a polyalkyleneoxy group or an alkyl group having from 1 to 4 carbon atoms and having at least one group selected from —OH, —OCH₃, —SO₃H and a salt thereof.

A hydroxyethyl group or a polyalkyleneoxy group is more preferred, and a polyalkyleneoxy group is particularly preferred. The polyalkyleneoxy group has the same meaning as the polyalkyleneoxy group described in formula (B).

Moreover, in order to improve adhesion property to the image-recording layer, it is preferred that the polymer has an ethylenically unsaturated bond. The acrylic polymer having a polyethyleneoxy group and an ethylenically unsaturated bond is most preferred.

As the ethylenically unsaturated bond, an ethylenically unsaturated group, for example, a (meth)acryl group, a vinyl group or an allyl group is preferred. The ethylenically unsaturated group can be introduced into the polymer by a polymer reaction or copolymerization. For instance, a reaction between an acrylic polymer having a carboxyl group in its side chain and glycidyl methacrylate or a reaction between an acrylic polymer having an epoxy group and a carboxylic acid containing an ethylenically unsaturated group, for example, methacrylic acid can be utilized.

In order to increase the affinity with the image-recording layer, the weight average molecular weight (Mw) of the polymer is preferably from 3,000 to 100,000, and more preferably from 8,000 to 100,000.

The method of determination of the Mw of the polymer is described below. The inorganic fine particles the surfaces of which are modified with the polymer are added to a 10% by weight sodium hydroxide solution so as to have solid content of 1% by weight and the aqueous solution is stirred at 25° C. for 24 hours to elute the inorganic fine particles. The aqueous solution is subjected to centrifugal separation and the polymer which has modified the surface of the inorganic fine particle is recovered. Using the polymer, the Mw is measured by gel permeation chromatography (HLC-8220 GPC, produced by Tosoh Corp.) using N,N-dimethylformamide as an eluent and calculated in terms of polyethylene oxide.

Specific examples of the polymer structure which modifies the surface of the inorganic fine particle according to the invention are set forth below, but the invention should not be construed as being limited thereto.

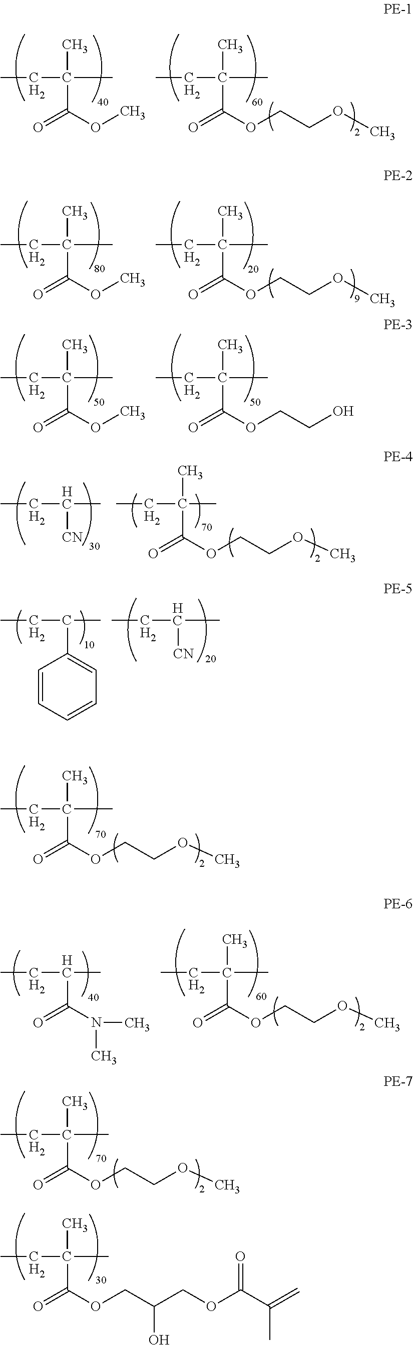

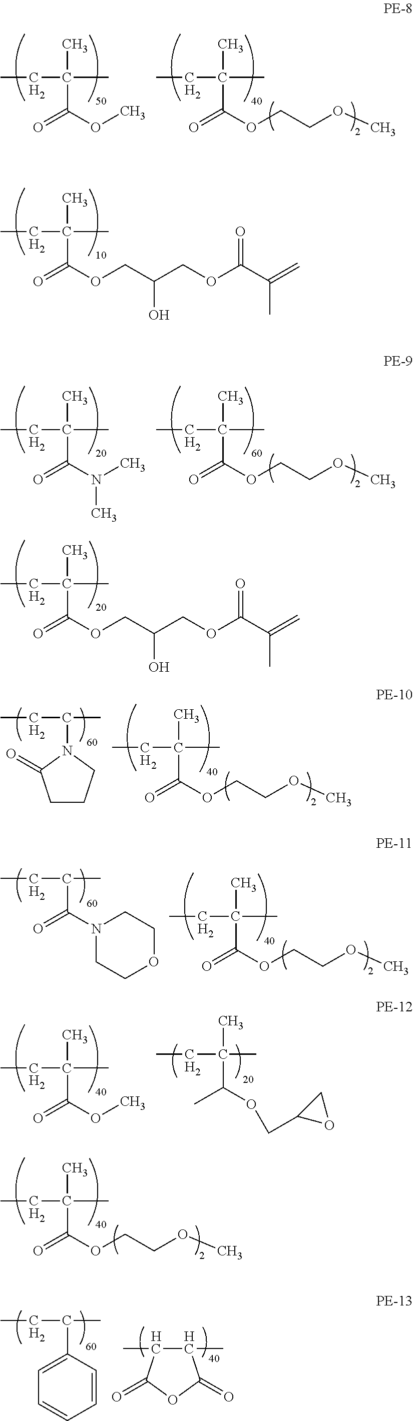

The amount of the inorganic fine particle the surface of which is modified with a polymer for use in the invention is ordinarily from 0.1 to 60% by weight, preferably from 0.5 to 25% by weight, based on the total solid content of the image-recording layer containing a polymer compound and the inorganic fine particle the surface of which is modified with a polymer. In the range described above, the effect of the inorganic fine particle the surface of which is modified with a polymer well exhibits and the film strength is also well maintained.

The constituting components of the image-recording layer other than the component (D) described above are described in detail below.

### (A) Infrared Absorbing Agent

The infrared absorbing agent has a function of converting the infrared ray absorbed to heat and a function of being excited by the infrared ray to perform electron transfer and/or energy transfer to a radical polymerization initiator described hereinafter. The infrared absorbing agent for use in the invention is preferably an infrared absorbing dye having an absorption maximum in a wavelength range of 760 to 1,200 nm.

As the infrared absorbing dye, compounds described in Paragraph Nos. [0058] to [0087] of JP-A-2008-195018 are used.

Of the dyes, cyanine dyes, squarylium dyes, pyrylium dyes and nickel thiolate complexes are particularly preferred. As the particularly preferable example of the dye, a cyanine dye represented by formula (a) shown below is exemplified.

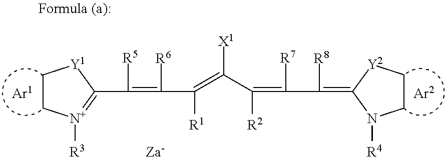

In formula (a), X′ represents a hydrogen atom, a halogen atom, —N(R⁹)(R¹⁰), X²-L¹ or a group shown below. R⁹ and R¹⁰, which may be the same or different, each represents an aromatic hydrocarbon group having from 6 to 10 carbon atoms, which may have a substituent, an alkyl group having from 1 to 8 carbon atoms, which may have a substituent or a hydrogen atom, or R⁹ and R¹⁰ may be combined with each other to form a ring. Among them, a phenyl group is preferable. X² represents an oxygen atom or a sulfur atom, L¹ represents a hydrocarbon group having from 1 to 12 carbon atoms, an aromatic ring group containing a hetero atom or a hydrocarbon group having from 1 to 12 carbon atoms and containing a hetero atom. The hetero atom used herein includes a nitrogen atom, a sulfur atom, an oxygen atom, a halogen atom and a selenium atom. In the group shown below, Xa⁻ has the same meaning as Za⁻ defined hereinafter, and R^{a} represents a hydrogen atom or a substituent selected from an alkyl group, an aryl group, a substituted or unsubstituted amino group and a halogen atom.

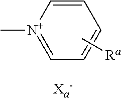

R¹ and R² each independently represents a hydrocarbon group having from 1 to 12 carbon atoms. In view of the preservation stability of a coating solution for image-recording layer, it is preferred that R¹ and R² each represents a hydrocarbon group having two or more carbon atoms. It is also preferred that R¹ and R² are combined with each other to form a 5-membered or 6-membered ring.

Ar¹ and Ar², which may be the same or different, each represents an aromatic hydrocarbon group which may have a substituent. Preferable examples of the aromatic hydrocarbon group include a benzene ring group and a naphthalene ring group. Also, preferable examples of the substituent include a hydrocarbon group having 12 or less carbon atoms, a halogen atom and an alkoxy group having 12 or less carbon atoms. Y¹ and Y², which may be the same or different, each represents a sulfur atom or a dialkylmethylene group having 12 or less carbon atoms. R³ and R⁴, which may be the same or different, each represents a hydrocarbon group having 20 or less carbon atoms, which may have a substituent. Preferable examples of the substituent include an alkoxy group having 12 or less carbon atoms, a carboxyl group and a sulfo group. R⁵, R⁶, R⁷ and R⁵, which may be the same or different, each represents a hydrogen atom or a hydrocarbon group having 12 or less carbon atoms. In view of the availability of raw materials, a hydrogen atom is preferred. Za⁻ represents a counter anion. However, Za⁻ is not necessary when the cyanine dye represented by formula (a) has an anionic substituent in the structure thereof and neutralization of charge is not needed. In view of the preservation stability of a coating solution for image-recording layer, preferable examples of the counter ion for Za⁻ include a halide ion, a perchlorate ion, a tetrafluoroborate ion, a hexafluorophosphate ion and a sulfonate ion, and particularly preferable examples thereof include a perchlorate ion, a hexafluorophosphate ion and an arylsulfonate ion.

Specific examples of the cyanine dye represented by formula (a), which can be preferably used in the invention, include those described in Paragraph Nos. [0017] to [0019] of JP-A-2001-133969, Paragraph Nos. [0012] to [0021] of JP-A-2002-23360 and Paragraph Nos. [0012] to [0037] of JP-A-2002-40638.

The infrared absorbing agents may be used individually or in combination of two or more thereof. Also, the infrared absorbing dye may be used together with an infrared absorbing agent other than the infrared absorbing dye, for example, a pigment. As the pigment, compounds described in Paragraph Nos. [0072] to of JP-A-2008-195018 are preferably used.

The content of the infrared absorbing agent in the image-recording layer according to the invention is preferably from 0.1 to 10.0% by weight, more preferably from 0.5 to 5.0% by weight, based on the total solid content of the image-recording layer.

### (B) Radical Polymerization Initiator

The radical polymerization initiator (B) for use in the invention is a compound which initiates or accelerates polymerization of a radical polymerizable compound (C). The radical polymerization initiator for use in the invention includes, for example, known thermal polymerization initiators, compounds containing a bond having small bond dissociation energy and photopolymerization initiators.

The radical polymerization initiators in the invention include, for example, (a) organic halides, (b) carbonyl compounds, (c) azo compounds, (d) organic peroxides, (e) metallocene compounds, (f) azido compounds, (g) hexaarylbiimidazole compounds, (h) organic borate compounds, (i) disulfone compounds, (j) oxime ester compounds and (k) onium salt compounds.

As the organic halides (a), compounds described in Paragraph Nos. [0022] to [0023] of JP-A-2008-195018 are preferred.

As the carbonyl compounds (b), compounds described in Paragraph No. [0024] of JP-A-2008-195018 are preferred.

As the azo compounds (c), for example, azo compounds described in JP-A-8-108621 are used.

As the organic peroxides (d), for example, compounds described in Paragraph No. [0025] of JP-A-2008-195018 are preferred.

As the metallocene compounds (e), for example, compounds described in Paragraph No. [0026] of JP-A-2008-195018 are preferred.

As the azido compounds (f), compound, for example, 2,6-bis(4-azidobenzylidene)-4-methylcyclohexanone is exemplified.

As the hexaarylbiimidazole compounds (g), for example, compounds described in Paragraph No. [0027] of JP-A-2008-195018 are preferred.

As the organic borate compounds (h), for example, compounds described in Paragraph No. [0028] of JP-A-2008-195018 are preferred.

As the disulfone compounds (i), for example, compounds described in JP-A-61-166544 and JP-A-2002-328465 are exemplified.

As the oxime ester compounds (j), for example, compounds described in Paragraph Nos. [0028] to [0030] of JP-A-2008-195018 are preferred.

As the onium salt compounds (k), onium salts, for example, diazonium salts described in S. I. Schlesinger, Photogr. Sci. Eng., 18, 387 (1974) and T. S. Bal et al., Polymer, 21, 423 (1980), ammonium salts described in U.S. Pat. No. 4,069,055 and JP-A-4-365049, phosphonium salts described in U.S. Pat. Nos. 4,069,055 and 4,069,056, iodonium salts described in European Patent 104,143, U.S. Patent Publication No. 2008/0311520, JP-A-2-150848 and JP-A-2008-195018, sulfonium salts described in European Patents 370,693, 390, 214, 233, 567, 297,443 and 297,442, U.S. Pat. Nos. 4,933,377, 4,760,013, 4,734,444 and 2,833,827, German Patents 2,904,626, 3,604,580 and 3,604,581, selenonium salts described in J. V. Crivello et al., Macromolecules, 10 (6), 1307 (1977) and J. V. Crivello et al., J. Polymer Sci., Polymer Chem. Ed., 17, 1047 (1979), arsonium salts described in C. S. Wen et al., Teh, Proc. Conf. Rad. Curing ASIA, p. 478, Tokyo, Oct. (1988), and azinium salts described in JP-A-2008-195018 are exemplified.

Of the radical polymerization initiators, the onium salts, particularly, the iodonium salts, sulfonium salts and azinium salts are preferable. Specific examples of these compounds are set forth below, but the invention should not be construed as being limited thereto.

Of the iodonium salts, diphenyliodonium salts are preferred, diphenyliodonium salts substituted with an electron donating group, for example, an alkyl group or an alkoxy group are more preferred, and asymmetric diphenyliodonium salts are still more preferred. Specific examples thereof include diphenyliodonium hexafluorophosphate,
4-methoxyphenyl-4-(2-methylpropyl)phenyliodonium hexafluorophosphate,
4-(2-methylpropyl)phenyl-p-tolyliodonium hexafluorophosphate,
4-hexyloxyphenyl-2,4,6-trimethoxyphenyliodonium hexafluorophosphate,
4-hexyloxyphenyl-2,4-diethoxyphenyliodonium tetrafluoroborate,
4-octyloxyphenyl-2,4,6-trimethoxyphenyliodonium 1-perfluorobutanesulfonate,
4-octyloxyphenyl-2,4,6-trimethoxyphenyliodonium hexafluorophosphate and bis(4-tert-butylphenyl)iodonium tetraphenylborate.

Examples of the sulfonium salt include triphenylsulfonium hexafluorophosphate, triphenylsulfonium benzoylformate, bis(4-chlorophenyl)phenylsulfonium benzoylformate, bis(4-chlorophenyl)-4-methylphenylsulfonium tetrafluoroborate and tris(4-chlorophenyl)sulfonium 3,5-bis(methoxycarbonyl)benzenesulfonate.

Examples of the azinium salt include 1-cyclohexylmethyloxypyridinium hexafluorophosphate, 1-cyclohexyloxy-4-phenylpyridinium hexafluorophosphate, 1-ethoxy-4-phenylpyridinium hexafluorophosphate, 1-(2-ethylhexyloxy)-4-phenylpyridinium hexafluorophosphate, 4-chloro-1-cyclohexylmethyloxypyridinium hexafluorophosphate, 1-ethoxy-4-cyanopyridinium hexafluorophosphate, 3,4-dichloro-1-(2-ethylhexyloxy)pyridinium hexafluorophosphate, 1-benzyloxy-4-phenylpyridinium hexafluorophosphate, 1-phenethyloxy-4-phenylpyridinium hexafluorophosphate, 1-(2-ethylhexyloxy)-4-phenylpyridinium p-toluenesulfonate, 1-(2-ethylhexyloxy)-4-phenylpyridinium perfluorobutanesulfonate, 1-(2-ethylhexyloxy)-4-phenylpyridinium bromide and 1-(2-ethylhexyloxy)-4-phenylpyridinium tetrafluoroborate.

The radical polymerization initiator can be added to the image-recording layer preferably in an amount from 0.1 to 50% by weight, more preferably from 0.5 to 30% by weight, particularly preferably from 0.8 to 20% by weight, based on the total solid content constituting the image-recording layer. In the range described above, good sensitivity and good stain resistance in the non-image area at the time of printing are obtained.

### (C) Radical Polymerizable Compound

The radical polymerizable compound (C) for use in the invention is an addition-polymerizable compound having at least one ethylenically unsaturated double bond, and it is preferably selected from compounds having at least one, preferably two or more, terminal ethylenically unsaturated double bonds. Such compounds are widely known in the field of art and they can be used in the invention without any particular limitation. The compound has a chemical form, for example, a monomer, a prepolymer, specifically, a dimer, a trimer or an oligomer, or a (co)polymer thereof, or a mixture thereof.

Specific examples of the radical polymerizable compound include compounds described in Paragraph Nos. [0089] to [0098] of JP-A-2008-195018. Among them, esters of aliphatic polyhydric alcohol compound with an unsaturated carboxylic acid (for example, acrylic acid, methacrylic acid, itaconic acid, crotonic acid, isocrotonic acid or maleic acid) are preferably exemplified. Other preferable radical polymerizable compound includes polymerizable compounds containing an isocyanuric acid structure described in JP-A-2005-329708.

Among them, a radical polymerizable compound having a polyalkyleneoxy group is preferred from the standpoint of balance between hydrophilicity relating to the on-press development property and polymerization ability relating to the printing durability and the stability of a coating solution containing the inorganic fine particle. Of the polyalkyleneoxy groups, a polyethyleneoxy group is most preferred. As the commercially available compounds, for example, M225 (produced by Toagosei Co., Ltd.) shown as Ex. 1 below, A-BPE-4 (produced by Shin-Nakamura Chemical Co., Ltd.) shown as Ex. 2 below, BPE-200 (produced by Shin-Nakamura Chemical Co., Ltd.) shown as Ex. 3 below, A-GLY-6E (produced by Shin-Nakamura Chemical Co., Ltd.) shown as Ex. 4 below, UA-6ELH (produced by Shin-Nakamura Chemical Co., Ltd.) shown as Ex. 5 below, U-12PLM, U-6PLP, UA-6PLTX, UA-12PLM, A-6ELH, UA-6ELTX, UA-12ELM and A-6ELH (all produced by Shin-Nakamura Chemical Co., Ltd.) are specifically exemplified.

Further, a radical polymerizable compound having a urethane bond and a polyalkyleneoxy group, for example, a compound obtained by reacting polyethylene glycol monoacrylate (AE-400, produced by NOF Corp., Mn: 512) with aliphatic polyisocyanate resin based on hexamethylene diisocyanate (N3200, produced by Bayer AG) is also preferred.

The structures of the compound are specifically set forth below, but the invention should not be construed as being limited thereto.

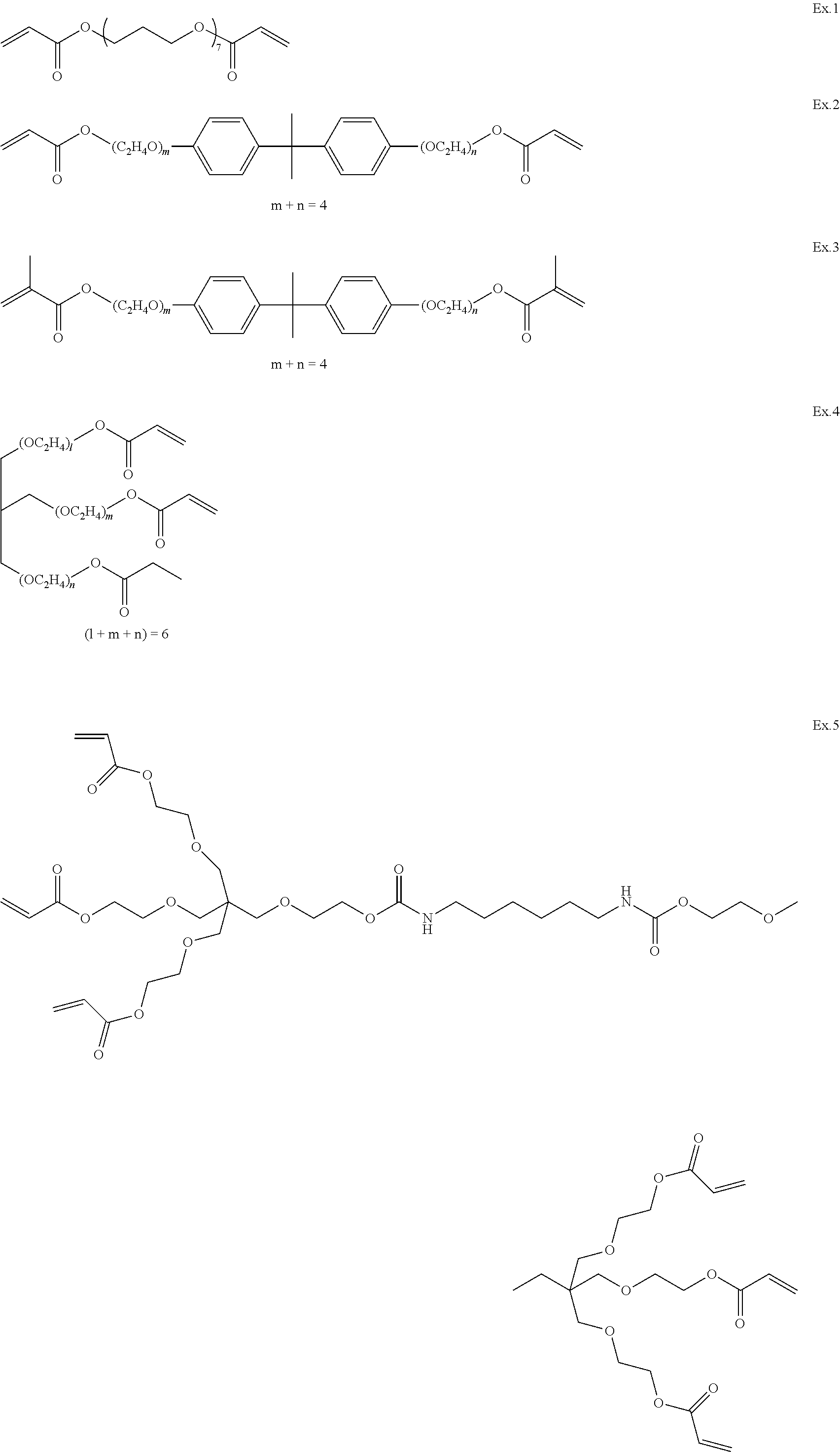

In the invention, the radical polymerizable compound (C) is preferably used in an amount from 5 to 80% by weight, more preferably from 25 to 75% by weight, based on the total solid content of the image-recording layer.

### (E) Polymer Compound

The image-recording layer according to the invention preferably contains a polymer compound in order to be imparted the on-press development property. In particular, a polymer compound having a polyalkyleneoxy group is preferred. The polymer compound having a polyalkyleneoxy group, particularly the polymer compound having a polyalkyleneoxy group in its side chain, may be incorporated into the image-recording layer in the form of a fine particle or as a medium (hereinafter, referred to as a binder) for compatibilizing or binding various materials of the image-recording layer without having a specific form, for example, form of a particle.

In any event, when the inorganic fine particle which has on its surface an acrylic polymer as a graft chain, particularly the inorganic fine particle having an ethyleneoxy group on its surface is used together with the polymer compound having a polyalkyleneoxy group in its side chain, the permeability of dampening water is remarkably increased to improve the on-press development property. Also, the dispersion stability of the inorganic fine particle in the coating solution is improved.

### (E-1) Polymer Fine Particle

According to the invention, a polymer fine particle can be used in order to improve the on-press development property. The polymer fine particle for use in the invention is preferably at least one fine particle selected from hydrophobic thermoplastic polymer fine particle, thermo-reactive polymer fine particle, microcapsule having a hydrophobic compound encapsulated therein and crosslinked polymer fine particle (microgel).

According to the invention, the polymer fine particle preferably has a polyalkylene oxide structure. In particular, a polyethyleneoxy group is preferred where the alkyleneoxy group is an ethyleneoxy group and a number of repeating unit of the ethyleneoxy is from 12 to 250.

In the case of the hydrophobic thermoplastic polymer fine particle or thermo-reactive polymer fine particle, the introduction of the polyalkylene oxide structure into the polymer fine particle is conducted, for example, according to a method of effecting emulsion polymerization or suspension polymerization of a monomer having a polyalkylene oxide structure corresponding to a repeating unit represented by formula (T-1) or (T-2) shown below, for example, an acrylate or methacrylate having a polyalkylene oxide structure. In such a case, as a copolymerizable monomer, ethylene, styrene, vinyl chloride, methyl acrylate, ethyl acrylate, methyl methacrylate, ethyl methacrylate, vinylidene chloride, acrylonitrile and vinyl carbazole are exemplified. Among them, styrene, acrylonitrile and methyl methacrylate are more preferably exemplified.

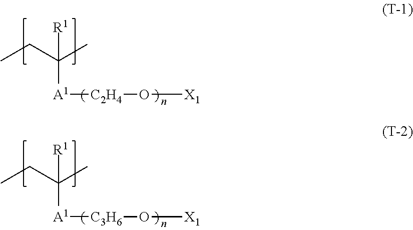

In formulae (T-1) and (T-2), R¹ represents a hydrogen atom or a methyl group, A¹ represents a divalent connecting group of —COO— or —CONH—, X₁ represents a hydrocarbon group having 3 or less carbon atoms or a hydrogen atom, and n represents an integer of 2 or more.

The hydrophobic thermoplastic polymer fine particle means fine particle which is fused by heat generated at the time of infrared laser exposure to hydrophobilize as described, for example, in Research Disclosure, No. 33303, January (1992), JP-A-9-123387, JP-A-9-131850, JP-A-9-171249, JP-A-9-171250 and European Patent 931,647.

The thermo-reactive polymer fine particle means a polymer fine particle forming a hydrophobilized region by crosslinkage due to thermal reaction and change in the functional group involved therein and includes a polymer fine particle having a thermo-reactive group.

As the thermo-reactive group of the polymer fine particle having a thermo-reactive group for use in the invention, a functional group performing any reaction can be used as long as a chemical bond is formed. For instance, an ethylenically unsaturated group (for example, an acryloyl group, a methacryloyl group, a vinyl group or an allyl group) performing a radical polymerization reaction, a cationic polymerizable group (for example, a vinyl group or a vinyloxy group), an isocyanate group performing an addition reaction or a blocked form thereof, an epoxy group, a vinyloxy group and a functional group having an active hydrogen atom (for example, an amino group, a hydroxy group or a carboxyl group) as the reaction partner thereof, a carboxyl group performing a condensation reaction and a hydroxyl group or an amino group as the reaction partner thereof, and an acid anhydride performing a ring opening addition reaction and an amino group or a hydroxyl group as the reaction partner thereof are preferably exemplified.

In the case of the microcapsule or microgel, the introduction of the polyalkylene oxide structure into the polymer fine particle is conducted according to a known method, for example, a method of adding, for example, polyalkylene oxide monoalkyl ether to the components of interfacial polymerization using a polyfunctional isocyanate by applying the descriptions of the polymer fine particle below.

As the microcapsule for use in the invention, microcapsule having all or part of the constituting components of the image-recording layer encapsulated therein as described, for example, in JP-A-2001-277740 and JP-A-2001-277742 is exemplified. The constituting components of the image-recording layer may be present outside the microcapsules. It is a more preferable embodiment of the image-recording layer containing microcapsules that hydrophobic constituting components are encapsulated in the microcapsules and hydrophilic components are present outside the microcapsules.

The image-recording layer according to the invention may be an embodiment containing a crosslinked resin particle, that is, a microgel. The microgel can contain a part of the constituting components of the image-recording layer inside and/or on the surface thereof. Particularly, an embodiment of a reactive microgel containing the radical polymerizable compound (C) on the surface thereof is preferred in view of the image-forming sensitivity and printing durability.

The average particle size of the polymer fine particle is preferably from 0.01 to 3.0 μm, more preferably from 0.05 to 2.0 μm, particularly preferably from 0.10 to 1.0 μm. In the range described above, good resolution and good time-lapse stability can be achieved.

The content of the polymer fine particle is preferably in a range of 5 to 90% by weight based on the total solid content of the image-recording layer.

### (E-2) Binder Polymer

In the image-recording layer according to the invention, a binder polymer can be used as a binder for each component of the image-recording layer and for the purpose of improving film strength of the image-recording layer. The binder polymer which can be used in the invention can be selected from those heretofore known without restriction, and polymers having a film-forming property are preferred. Among them, acrylic resins, polyvinyl acetal resins and polyurethane resins are preferred.

It is particularly preferred that the binder polymer has a polyalkylene oxide structure as a hydrophilic group from the standpoint of improving the on-press development property. A polyethyleneoxy group is preferred where the alkyleneoxy group is an ethyleneoxy group and a number of repeating unit of the ethyleneoxy is from 2 to 8. An acrylic resin obtained by copolymerization of a monomer having a polyalkylene oxide structure corresponding to a repeating unit represented by formula (T-1) or (T-2) shown above is particularly preferred.

For the purpose of increasing the adhesion property to the inorganic fine particle or the purpose of increasing the adhesion property to the image-recording layer, it is preferred that the binder polymer incorporated into the image-recording layer is a polymer having an ethyleneoxy group. Also, a monomer or oligomer having an ethylenically unsaturated bond incorporated into the image-recording layer preferably has an ethyleneoxy group and more preferably an ethyleneoxy group having a polymerization degree of 20 or more.

In order to control the ink-receptive property, an oleophilic group, for example, an alkyl group, an aryl group, an aralkyl group or an alkenyl group may be introduced into the binder polymer according to the invention. Specifically, an oleophilic group-containing monomer, for example, an alkyl methacrylate may be copolymerized.

As the binder polymer preferable for the invention, a polymer having a crosslinkable functional group for increasing film strength of the image area in its main chain or side chain, preferably in its side chain, as described in JP-A-2008-195018 is exemplified. Due to the crosslinkable functional group, crosslinkage is formed between the polymer molecules to facilitate curing.

As the crosslinkable functional group, an ethylenically unsaturated group, for example, a (meth)acryl group, a vinyl group or an allyl group or an epoxy group is preferred. The crosslinkable functional group can be introduced into the polymer by a polymer reaction or copolymerization. For instance, a reaction between an acrylic polymer or polyurethane having a carboxyl group in its side chain and glycidyl methacrylate or a reaction between a polymer having an epoxy group and a carboxylic acid containing an ethylenically unsaturated group, for example, methacrylic acid can be utilized.

The content of the crosslinkable group in the binder polymer is preferably from 0.1 to 10.0 mmol, more preferably from 1.0 to 7.0 mmol, most preferably from 2.0 to 5.5 mmol, based on 1 g of the binder polymer.

Moreover, the binder polymer may further contain a hydrophilic group other than the polyalkylene oxide structure. The other hydrophilic group includes, for example, a hydroxy group, a carboxyl group, an amino group, an ammonium group, an amido group, a sulfo group and a phosphoric acid group. The hydrophilic group contributes to impart the on-press development property to the image-recording layer. In particular, coexistence of the crosslinkable group and the hydrophilic group makes it possible to maintain good balance between the printing durability and developing property.

In order to introduce the hydrophilic group into the binder polymer, a monomer having the hydrophilic group may be copolymerized.

Specific examples (1) to (11) of the binder polymer for use in the invention are set forth below, but the invention should not be construed as being limited thereto.

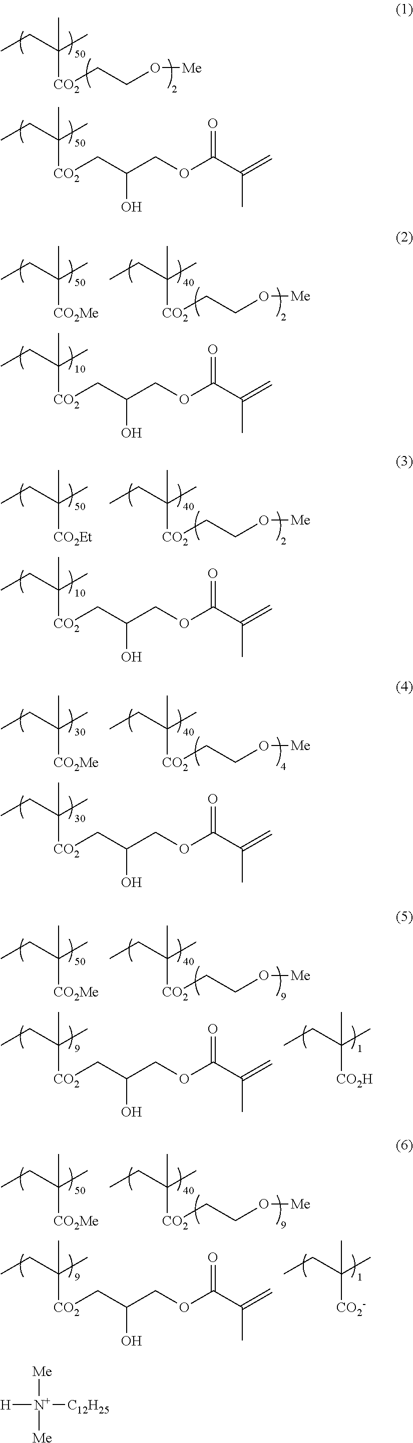

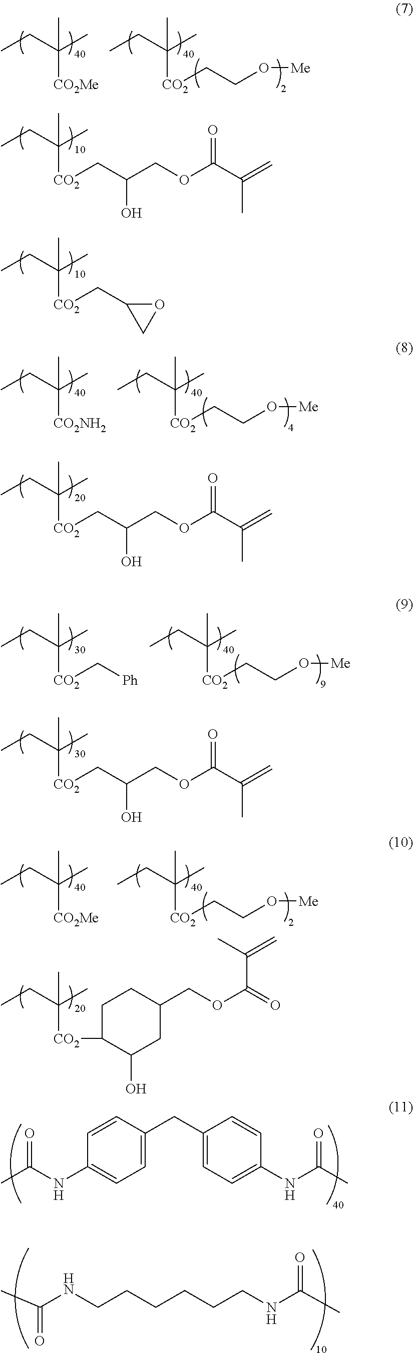

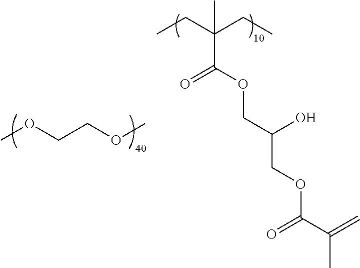

The weight average molecular weight (Mw) of the binder polymer according to the invention is preferably 2,000 or more, more preferably 5,000 or more, and still more preferably from 10,000 to 300,000.

According to the invention, a hydrophilic polymer, for example, polyacrylic acid or polyvinyl alcohol described in JP-A-2008-195018 may be used, if desired. Further, an oleophilic binder polymer is used together with a hydrophilic binder polymer.

The content of the binder polymer is ordinarily from 5 to 90% by weight, preferably from 5 to 80% by weight, more preferably from 10 to 70% by weight, based on the total solid content of the image-recording layer.

### (F) Hydrophilic Low Molecular Weight Compound

The image-recording layer according to the invention may contain a hydrophilic low molecular weight compound in order to improve the on-press development property without accompanying the deterioration of the printing durability.

The hydrophilic low molecular weight compound includes a water-soluble organic compound, for example, a glycol compound, e.g., ethylene glycol, diethylene glycol, triethylene glycol, propylene glycol, dipropylene glycol or tripropylene glycol, or an ether or ester derivative thereof, a polyhydroxy compound, e.g., glycerine, pentaerythritol or tris(2-hydroxyethyl)isocyanurate, an organic amine compound, e.g., triethanolamine, diethanolamine or monoethanolamine, or a salt thereof, an organic sulfonic acid compound, e.g., an alkyl sulfonic acid, toluene sulfonic acid or benzene sulfonic acid, or a salt thereof, an organic sulfamic acid compound, e.g., an alkyl sulfamic acid, or a salt thereof, an organic sulfuric acid compound, e.g., an alkyl sulfuric acid or an alkyl ether sulfuric acid, or a salt thereof, an organic phosphonic acid compound, e.g., phenyl phosphonic acid, or a salt thereof, an organic carboxylic acid, e.g., tartaric acid, oxalic acid, citric acid, malic acid, lactic acid, gluconic acid or an amino acid, or a salt thereof and a betaine compound.

According to the invention, it is preferred that at least one compound selected from a polyol compound, an organic sulfate compound, an organic sulfonate compound and a betaine compound is incorporated.

Specific examples of the organic sulfonate compound include an alkylsulfonate, for example, sodium n-butylsulfonate, sodium n-hexylsulfonate, sodium 2-ethylhexylsulfonate, sodium cyclohexylsulfonate or sodium n-octylsulfonate, an alkylsulfonate containing an ethyleneoxy group, for example, sodium 5,8,11-trioxapentadecane-1-sulfonate, sodium 5,8,11-trioxaheptadecane-1-sulfonate, sodium 13-ethyl-5,8,11-trioxaheptadecane-1-sulfonate or sodium 5,8,11,14-tetraoxatetracosane-1-sulfonate, and an arylsulfonate, for example, sodium benzenesulfonate, sodium p-toluenesulfonate, sodium p-hydroxybenzenesulfonate, sodium p-styrenesulfonate, sodium isophthalic acid dimethyl-5-sulfonate, sodium 1-naphtylsulfonate, sodium 4-hydroxynaphtylsulfonate, disodium 1,5-naphthalenedisulfonate or trisodium 1,3,6-naphthalenetrisulfonate. The salt may also be potassium salt or lithium salt.

The organic sulfate compound includes a sulfate of alkyl, alkenyl, alkynyl, aryl or heterocyclic monoether of polyethylene oxide. The number of unit of ethylene oxide is preferably from 1 to 4. The salt is preferably a sodium salt, a potassium salt or a lithium salt.

As the betaine compound, a compound wherein a number of carbon atoms included in a hydrocarbon substituent on the nitrogen atom is from 1 to 5 is preferred. Specific examples thereof include trimethylammonium acetate, dimethylpropylammonium acetate, 3-hydroxy-4-trimethylammoniobutyrate, 4-(1-pyridinio)butyrate, 1-hydroxyethyl-1-imidazolioacetate, trimethylammonium methanesulfonate, dimethylpropylammonium methanesulfonate, 3-trimethylammonio-1-porpanesulfonate and 3-(1-pyridinio)-1-porpanesulfonate.

Since the hydrophilic low molecular weight compound has a small structure of hydrophobic portion and almost no surface active function, degradations of the hydrophobicity and film strength in the image area due to penetration of dampening water into the exposed area (image area) of the image-recording layer are prevented and thus, the ink receptive-property and printing durability of the image-recording layer can be preferably maintained.

The amount of the hydrophilic low molecular weight compound added to the image-recording layer is preferably from 0.5 to 20% by weight, more preferably from 1 to 10% by weight, still more preferably from 2 to 8% by weight, based on the total solid content of the image-recording layer. In the range described above, good on-press development property and good printing durability are achieved.

The hydrophilic low molecular weight compounds may be used individually or as a mixture of two or more thereof.

### (G) Oil-Sensitizing Agent

In order to improve the ink-receptive property, an oil-sensitizing agent, for example, a phosphonium compound, a nitrogen-containing low molecular weight compound or an ammonium group-containing polymer can be used in the image-recording layer. In particular, in the case where an inorganic stratiform compound is incorporated into a protective layer described hereinafter, the oil-sensitizing agent functions as a surface covering agent of the inorganic stratiform compound and prevents deterioration of the ink-receptive property during printing due to the inorganic stratiform compound.

As preferable examples of the phosphonium compound, phosphonium compounds described in JP-A-2006-297907 and JP-A-2007-50660 are exemplified. Specific examples of the phosphonium compound include tetrabutylphosphonium iodide, butyltriphenylphosphonium bromide, tetraphenylphosphonium bromide, 1,4-bis(triphenylphosphonio)butane di(hexafluorophosphate), 1,7-bis(triphenylphosphonio) heptane sulfate and 1,9-bis(triphenylphosphonio) nonane naphthalene-2,7-disulfonate.

As the nitrogen-containing low molecular weight compound, an amine salt and a quaternary ammonium salt are exemplified. Also, an imidazolinium salt, a benzimidazolinium salt, a pyridinium salt and a quinolinium salt are exemplified. Of the nitrogen-containing low molecular weight compounds, the quaternary ammonium salt and pyridinium salt are preferably used. Specific examples the nitrogen-containing low molecular weight compound include tetramethylammonium hexafluorophosphate, tetrabutylammonium hexafluorophosphate, dodecyltrimethylammonium p-toluenesulfonate, benzyltriethylammonium hexafluorophosphate, benzyldimethyloctylammonium hexafluorophosphate and benzyldimethyldodecylammonium hexafluorophosphate.

The ammonium group-containing polymer may be any polymer containing an ammonium group in its structure and is preferably a polymer containing from 5 to 80% by mole of (meth)acrylate having an ammonium group in its side chain as a copolymerization component.

As to the ammonium group-containing polymer, its reduced specific viscosity value (unit: cSt/g/ml) determined according to the measurement method described below is preferably from to 120, more preferably from 10 to 110, particularly preferably from 15 to 100.

### <Measurement Method of Reduced Specific Viscosity>

In a 20 ml measuring flask was weighed 3.33 g of a 30% polymer solution (1 gas a solid content) and the measuring flask was filled up to the gauge line with N-methylpyrrolidone. The resulting solution was put into an Ubbelohde viscometer (viscometer constant: 0.010 cSt/s) and a period for running down of the solution at 30° C. was measured. The viscosity was determined in a conventional manner according to the following calculation formula:

Kinetic viscosity=Viscometer constant×Period for liquid to pass through a capillary (sec)

Specific examples of the ammonium group-containing polymer are set forth below.

(1) 2-(Trimethylammonio)ethyl methacrylate p-toluenesulfonate/3,6-dioxaheptyl methacrylate copolymer (molar ratio: 10/90)
(2) 2-(Trimethylammonio)ethyl methacrylate hexafluorophosphate/3,6-dioxaheptyl methacrylate copolymer (molar ratio: 20/80)
(3) 2-(Ethyldimethylammonio)ethyl methacrylate p-toluenesulfonate/hexyl methacrylate copolymer (molar ratio: 30/70)
(4) 2-(Trimethylammonio)ethyl methacrylate hexafluorophosphate/2-ethylhexyl methacrylate copolymer (molar ratio: 20/80)
(5) 2-(Trimethylammonio)ethyl methacrylate methylsulfate/hexyl methacrylate copolymer (molar ratio: 40/60)
(6) 2-(Butyldimethylammonio)ethyl methacrylate hexafluorophosphate/3,6-dioxaheptyl methacrylate copolymer (molar ratio: 20/80)
(7) 2-(Butyldimethylammonio)ethyl acrylate hexafluorophosphate/3,6-dioxaheptyl methacrylate copolymer (molar ratio: 20/80)
(8) 2-(Butyldimethylammonio)ethyl methacrylate 13-ethyl-5,8,11-trioxa-1-heptadecanesulfonate/3,6-dioxaheptyl methacrylate copolymer (molar ratio: 20/80)
(9) 2-(Butyldimethylammonio)ethyl methacrylate hexafluorophosphate/3,6-dioxaheptyl methacrylate/2-hydroxy-3-methacryloyloxypropyl methacrylate copolymer (molar ratio: 15/80/5)

The content of the oil-sensitizing agent is preferably from 0.01 to 30.0% by weight, more preferably from 0.1 to 15.0% by weight, still more preferably from 1 to 5% by weight, based on the total solid content of the image-recording layer.

### (H) Other Components

Other components, for example, a surfactant, a coloring agent, a print-out agent, a polymerization inhibitor, a higher fatty acid derivative, a plasticizer, a co-sensitizer or a chain transfer agent may further be added to the image-recording layer. Specifically, compounds and amounts added thereof described, for example, in Paragraph Nos. [0114] to [0159] of JP-A-2008-284817, Paragraph Nos. [0023] to [0027] of JP-A-2006-91479 and Paragraph No. [0060] of U.S. Patent Publication No. 2008/0311520 are preferably used.

### (I) Formation of Image-Recording Layer

The image-recording layer according to the invention is formed by dispersing or dissolving each of the necessary constituting components described above in a known solvent to prepare a coating solution and coating the solution on a support by a known method, for example, bar coater coating and drying as described in Paragraph Nos. [0142] to [0143] of JP-A-2008-195018. The coating amount (solid content) of the image-recording layer formed on a support after coating and drying may be varied according to the intended purpose but is in general preferably from 0.3 to 3.0 g/m². In the range described above, good sensitivity and good film property of the image-recording layer can be achieved.

### (Undercoat Layer)

In the lithographic printing plate precursor according to the invention, an undercoat layer (also referred to as an intermediate layer) is preferably provided between the image-recording layer and the support. The undercoat layer strengthens adhesion between the support and the image-recording layer in the exposed area and makes removal of the image-recording layer from the support in the unexposed area easy, thereby contributing improvement in the developing property without accompanying degradation of the printing durability. Further, it is advantageous that in the case of infrared laser exposure, since the undercoat layer acts as a heat insulating layer, decrease in sensitivity due to diffusion of heat generated upon the exposure into the support is prevented.

As a compound for use in the undercoat layer, specifically, for example, a silane coupling agent having an addition-polymerizable ethylenic double bond reactive group described in JP-A-10-282679 and a phosphorus compound having an ethylenic double bond reactive group described in JP-A-2-304441 are exemplified. A polymer resin having an adsorbing group capable of adsorbing to a surface of the support, a hydrophilic group and a crosslinkable group as described in JP-A-2005-125749 and JP-A-2006-188038 is more preferably exemplified. The polymer resin is preferably a copolymer of a monomer having an adsorbing group, a monomer having a hydrophilic group and a monomer having a crosslinkable group. More specifically, a polymer resin which is a copolymer of a monomer having an adsorbing group, for example, a phenolic hydroxy group, a carboxyl group, —PO₃H₂, —OPO₃H₂, —CONHSO₂—, —SO₂NHSO₂— or —COCH₂COCH₃, a monomer having a hydrophilic sulfo group and a monomer having a polymerizable crosslinkable group, for example, a methacryl group or an allyl group is preferred. The polymer resin may contain a crosslinkable group introduced by a salt formation between a polar substituent of the polymer resin and a compound containing a substituent having a counter charge to the polar substituent of the polymer resin and an ethylenically unsaturated bond and also may be further copolymerized with a monomer other than those described above, preferably a hydrophilic monomer.

The content of the unsaturated double bond in the polymer resin for undercoat layer is preferably from 0.1 to 10.0 mmol, most preferably from 2.0 to 5.5 mmol, based on 1 g of the polymer resin.

The weight average molecular weight of the polymer resin for undercoat layer is preferably 5,000 or more, more preferably from 10,000 to 300,000.

The undercoat layer according to the invention may contain a chelating agent, a secondary or tertiary amine, a polymerization inhibitor or a compound containing an amino group or a functional group having polymerization inhibition ability and a group capable of interacting with the surface of aluminum support (for example, 1,4-diazobicyclo[2,2,2]octane (DABCO), 2,3,5,6-tetrahydroxy-p-quinone, chloranil, sulfophthalic acid, hydroxyethylethylenediaminetriacetic acid, dihydroxyethylethylenediaminediacetic acid or hydroxyethyliminodiacetic acid) in addition to the compounds for the undercoat layer described above in order to prevent the occurrence of stain due to preservation of the lithographic printing plate precursor.

The undercoat layer is coated according to a known method. The coating amount (solid content) of the undercoat layer is preferably from 0.1 to 100 mg/m², and more preferably from 1 to 30 mg/m².

### (Support)

As the support for use in the lithographic printing plate precursor according to the invention, a known support can be used. Particularly, an aluminum plate subjected to roughening treatment and anodizing treatment according to a known method is preferred.

Also, other treatments, for example, an enlarging treatment or a sealing treatment of micropores of the anodized film described in JP-A-2001-253181 and JP-A-2001-322365 or a surface hydrophilizing treatment, for example, with an alkali metal silicate as described in U.S. Pat. Nos. 2,714,066, 3,181,461, 3,280,734 and 3,902,734 or polyvinyl phosphonic acid as described in U.S. Pat. Nos. 3,276,868, 4,153,461 and 4,689,272 may be appropriately selected and applied to the aluminum plate, if desired.

The support preferably has a center line average roughness of 0.10 to 1.2 μm.

The support may have a backcoat layer containing an organic polymer compound described in JP-A-5-45885 or an alkoxy compound of silicon described in JP-A-5-45885, provided on the back surface thereof, if desired.

### (Protective Layer)

As for the lithographic printing plate precursor according to the invention, it is preferred to provide a protective layer (overcoat layer) on the image-recording layer. The protective layer has a function for preventing, for example, occurrence of scratch in the image-recording layer or ablation caused by exposure with a high illuminance laser beam, in addition to the function for restraining an inhibition reaction against the image formation by means of oxygen blocking.

With respect to the protective layer having such properties, there are described, for example, in U.S. Pat. No. 3,458,311 and JP-B-55-49729 (the term “JP-B” as used herein means an “examined Japanese patent publication”). As a polymer having low oxygen permeability for use in the protective layer, any water-soluble polymer and water-insoluble polymer can be appropriately selected to use. Specifically, for example, polyvinyl alcohol, a modified polyvinyl alcohol, polyvinyl pyrrolidone, a water-soluble cellulose derivative and poly(meth)acrylonitrile are exemplified.

It is also preferred that the protective layer contains an inorganic stratiform compound, for example, natural mica or synthetic mica as described in JP-A-2005-119273 in order to increase the oxygen blocking property.

Further, the protective layer may contain a known additive, for example, a plasticizer for imparting flexibility, a surfactant for improving a coating property or a fine inorganic particle for controlling a surface slipping property. The oil-sensitizing agent described with respect to the image-recording layer may also be incorporated into the protective layer.

The protective layer is coated according to a known method. The coating amount of the protective layer is preferably in a range of 0.01 to 10 g/m², more preferably in a range of 0.02 to 3 g/m², most preferably in a range of 0.02 to 1 g/m², in terms of the coating amount after drying.

### [Plate Making Method]

Plate making of the lithographic printing plate precursor according to the invention is preferably performed by an on-press development method. The on-press development method includes a step in which the lithographic printing plate precursor is imagewise exposed and a printing step in which oily ink and an aqueous component are supplied to the exposed lithographic printing plate precursor without undergoing any development processing to perform printing, and it is characterized in that the unexposed area of the lithographic printing plate precursor is removed in the course of the printing step. The imagewise exposure may be performed on a printing machine after the lithographic printing plate precursor is mounted on the printing machine or may be separately performed using a platesetter or the like. In the latter case, the exposed lithographic printing plate precursor is mounted as it is on a printing machine without undergoing a development processing step. Then, the printing operation is initiated using the printing machine with supplying oily ink and an aqueous component and at an early stage of the printing the on-press development processing is carried out. Specifically, the image-recording layer in the unexposed area is removed and the hydrophilic surface of support is revealed therewith to form the non-image area. As the oily ink and aqueous component, printing ink and dampening water for conventional lithographic printing can be employed, respectively. The on-press development method is described in more detail below.

The light source used for the image exposure in the invention is preferably a laser. The laser for use in the invention is not particularly restricted and preferably includes, for example, a solid laser or semiconductor laser emitting an infrared ray having a wavelength of 760 to 1,200 nm.

With respect to the infrared ray laser, the output is preferably 100 mW or more, the exposure time per pixel is preferably within 20 microseconds, and the irradiation energy is preferably from 10 to 300 mJ/cm². With respect to the laser exposure, in order to shorten the exposure time, it is preferred to use a multibeam laser device.

The exposed lithographic printing plate precursor is mounted on a plate cylinder of a printing machine. In case of using a printing machine equipped with a laser exposure apparatus, the lithographic printing plate precursor is mounted on a plate cylinder of the printing machine and then subjected to the imagewise exposure.

When at least any one of dampening water and printing ink is supplied to the imagewise exposed lithographic printing plate precursor to perform printing, in the exposed area of the image-recording layer, the image-recording layer cured by the exposure forms the printing ink receptive area having the oleophilic surface. On the other hand, in the unexposed area, the uncured image-recording layer is removed by dissolution or dispersion with the dampening water and/or printing ink supplied to reveal the hydrophilic surface in the area. As a result, the dampening water adheres on the revealed hydrophilic surface and the printing ink adheres to the exposed area of the image-recording layer, whereby printing is initiated.

While either the dampening water or printing ink may be supplied at first on the surface of lithographic printing plate precursor, it is preferred to supply the printing ink at first in view of preventing the dampening water from contamination with the component of the image-recording layer removed. Thus, the lithographic printing plate precursor according to the invention is subjected to the on-press development on an offset printing machine and used as it is for printing a large number of sheets.

### EXAMPLES

The present invention will be described in more detail with reference to the following examples, but the invention should not be construed as being limited thereto.

[Preparation of Inorganic Fine Particles OMP-1 to OMP-9 Surface Modified with Polymer]

The inorganic fine particle the surface of which is modified with the polymer is prepared in two steps of modifying the inorganic fine particle with a thiol compound which is radical polymerizable with the inorganic fine particle and then conducting radical polymerization.

### 1. Syntheses Example 1 of Inorganic Fine Particle Modified with Silane Coupling Agent

### UP-1

Into a high speed stirrer, 10 g of silica fine particle (SNOWTEX XL produced by Nissan Chemical Industries, Ltd., average particle size: 40 to 60 nm), 5 g of (3-mercaptopropyl)triethoxysilane, 5 g of an aqueous 25% by weight ammonia solution and 200 m of ethanol were charged and the mixture was stirred at 18,000 rpm for 24 hours at 25° C. After the completion of the stirring, the content in the flask was separated into the ethanol solution and the precipitate by a centrifugal at 7,000 rpm for 30 minutes. The precipitate was dispersed in 400 ml of acetone using an ultrasonic disperser and after the dispersion the resulting mixture was separated again by a centrifugal. The operation of acetone washing was further repeated twice and the resulting precipitate was dried naturally to obtain 12 g of white powder.

### 2. Syntheses Example 2 of Inorganic Fine Particle Modified with Silane Coupling Agent

### UP-2

UP-2 was prepared in the same manner as in Synthesis example 1 except for changing the silica fine particle (SNOWTEX XL produced by Nissan Chemical Industries, Ltd., average particle size: 40 to 60 nm) to silica fine particle (SNOWTEX MP-2040 produced by Nissan Chemical Industries, Ltd., average particle size: 200 nm).

### 3. Syntheses Example 3 of Inorganic Fine Particle Modified with Silane Coupling Agent

### UP-3

To 184 g of water was added 16 g of synthetic mica (SOMASIF ME-100, produced by CO—OP Chemical Co., Ltd., aspect ratio: 1,000 or more) and the mixture was dispersed using a homogenizer until an average particle size (according to a laser scattering method) became 3 μm to prepare a mica dispersion. Into a high speed stirrer, 100 g of the mica dispersion, 5 g of (3-mercaptopropyl)triethoxysilane, 5 g of an aqueous 25% by weight ammonia solution and 100 m of ethanol were charged and the mixture was stirred at 18,000 rpm for 24 hours at 25° C. After the completion of the stirring, the content in the flask was separated into the ethanol solution and the precipitate by a centrifugal at 7,000 rpm for 30 minutes. The precipitate was dispersed in 400 ml of acetone using an ultrasonic disperser and after the dispersion the resulting mixture was separated again by a centrifugal. The operation of acetone washing was further repeated twice and the resulting precipitate was dried naturally to obtain 10 g of white powder.

### 4. Syntheses Example 1 of Inorganic Fine Particle Surface Modified with Polymer

### OMP-1

Into a 500-ml 3-necked flask was charged 50 g of N-methylpyrrolidone, followed by heated at 80° C. with stirring under nitrogen stream. A mixed solution of 10 g (0.10 mol) of methyl methacrylate, 28.2 g (0.15 mol) of BLENMER PME-100 shown below, 0.5 g of Inorganic fine particle modified with silane coupling agent UP-1, 462 mg (2.00 mmol) of 2,2-azobis(2,4-dimethylvaleronitrile) and 30 g of dimethylsulfoxide was dropwise added thereto over a period of one hour. After the completion of the dropwise addition, the mixture was further heated with stirring for 10 hours. After the completion of the reaction, the mixture was allowed to cool to room temperature and the content in the flask was separated into the N-methylpyrrolidone solution and the precipitate by a centrifugal at 7,000 rpm for 30 minutes. The precipitate was dispersed in 400 ml of acetone using an ultrasonic disperser and after the dispersion the resulting mixture was separated again by a centrifugal. The operation of acetone washing was further repeated twice and the resulting precipitate was dried naturally to obtain white powder. The weight average molecular weight (Mw) of the polymer modified on the surface of the inorganic fine polymer was 12,000.

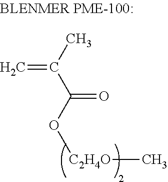

### 5. Syntheses Example 2 of Inorganic Fine Particle Surface Modified with Polymer

### OMP-2

Inorganic fine particle OMP-2 was prepared in the same manner as in Syntheses example 1 of Inorganic fine particle surface modified with polymer: OMP-1 except for changing 28.2 g (0.15 mol) of BLENMER PME-100 to 17.4 g (0.15 mol) of hydroxyethyl methacrylate. The weight average molecular weight (Mw) of the polymer modified on the surface of the inorganic fine polymer was 10,000.

### 6. Syntheses Example 3 of Inorganic Fine Particle Surface Modified with Polymer

### OMP-3

Into a 500-ml 3-necked flask was charged 50 g of N-methylpyrrolidone, followed by heated at 80° C. with stirring under nitrogen stream. A mixed solution of 10 g (0.10 mol) of methyl methacrylate, 15.0 g (0.08 mol) of BLENMER PME-100, 1.5 g (0.02 mol) of acrylic acid, 0.5 g of Inorganic fine particle modified with silane coupling agent UP-1, 462 mg (2.00 mmol) of 2,2-azobis(2,4-dimethylvaleronitrile) and 10 g of dimethylsulfoxide was dropwise added thereto over a period of one hour. After the completion of the dropwise addition, the mixture was further heated with stirring for 10 hours. After cooling, 3.84 g (0.03 mol) of glycidyl methacrylate and 0.1 g of p-methoxyphenol were added thereto and the mixture was stirred at 90° C. for 10 hours. The content in the flask was separated into the N-methylpyrrolidone solution and the precipitate by a centrifugal at 7,000 rpm for 30 minutes. The precipitate was dispersed in 400 ml of acetone using an ultrasonic disperser and after the dispersion the resulting mixture was separated again by a centrifugal. The operation of acetone washing was further repeated twice and the resulting precipitate was dried naturally to obtain white powder. The weight average molecular weight (Mw) of the polymer modified on the surface of the inorganic fine polymer was 9,000.

### 7. Syntheses Example 4 of Inorganic Fine Particle Surface Modified with Polymer

### OMP-4

Inorganic fine particle OMP-4 was prepared in the same manner as in Syntheses example 1 of Inorganic fine particle surface modified with polymer: OMP-1 except for changing 462 mg (2.00 mmol) of 2,2-azobis(2,4-dimethylvaleronitrile) to 1.15 g (5.00 mmol) of 2,2-azobis(2,4-dimethylvaleronitrile). The weight average molecular weight (Mw) of the polymer modified on the surface of the inorganic fine polymer was 5,000.

### 8. Syntheses Example 5 of Inorganic Fine Particle Surface Modified with Polymer

### OMP-5

Inorganic fine particle OMP-5 was prepared in the same manner as in Syntheses example 1 of Inorganic fine particle surface modified with polymer: OMP-1 except for changing Inorganic fine particle modified with silane coupling agent UP-1 to Inorganic fine particle modified with silane coupling agent UP-2. The weight average molecular weight (Mw) of the polymer modified on the surface of the inorganic fine polymer was 12,000.

### 9. Syntheses Example 6 of Inorganic Fine Particle Surface Modified with Polymer

### OMP-6

Inorganic fine particle OMP-6 was prepared in the same manner as in Syntheses example 1 of Inorganic fine particle surface modified with polymer: OMP-1 except for changing Inorganic fine particle modified with silane coupling agent UP-1 to Inorganic fine particle modified with silane coupling agent UP-3. The weight average molecular weight (Mw) of the polymer modified on the surface of the inorganic fine polymer was 12,000.

### 10. Syntheses Example 7 of Inorganic Fine Particle Surface Modified with Polymer

### OMP-7

Into a 500-ml 3-necked flask were charged 50 g of BLENMER PME-100, 3.4 g of mercaptopropyltrimethoxysilane and 220 g of dimethylacetamide and to the mixture was added 0.5 g of 2,2-azobis(2,4-dimethylvaleronitrile) at 65° C. under nitrogen stream. The mixture was maintained at the same temperature with stirring for 6 hours and then cooled to room temperature. The mixture was poured into 2 liters of ethyl acetate and the solid deposited was collected by filtration and washed with water to obtain the specific acrylic polymer. The weight of the polymer after drying was 52.4 g. It is confirmed that the polymer has a weight average molecular weight (Mw) measured by GPC and calculated in terms of standard polystyrene of 3,000 and a structure shown below determined by ¹³C-NMR (DMSO-d 6) where a trimethoxysilyl group (50.0 ppm) is introduced into the terminal.

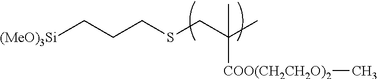

Into a high speed stirrer, 10 g of silica fine particle (SNOWTEX XL produced by Nissan Chemical Industries, Ltd., average particle size: 40 to 60 nm), 5 g of the specific polymer (Compound 1 described hereinbefore), 5 g of an aqueous 25% by weight ammonia solution, 50 m of ethanol and 150 ml of N,N-dimethylformamide were charged and the mixture was stirred and mixed at 18,000 rpm for 24 hours at 25° C. After the completion of the stirring, the content in the flask was separated into the ethanol/N,N-dimethylformamide solution and the precipitate by a centrifugal at 7,000 rpm for 30 minutes. The precipitate was dispersed in 400 ml of acetone using an ultrasonic disperser and after the dispersion the resulting mixture was separated again by a centrifugal. The operation of acetone washing was further repeated twice and the resulting precipitate was dried naturally to obtain 11 g of white powder.

### 11. Syntheses Example 8 of Inorganic Fine Particle Surface Modified with Polymer

### OMP-8

Inorganic fine particle OMP-8 was synthesized in the same manner as in Syntheses example 7 of OMP-7 except for changing BLENMER PME-100 to BLENMER PME-400 shown below.

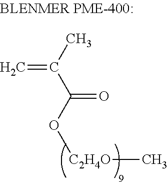

### 12. Syntheses Example 9 of Inorganic Fine Particle Surface Modified with Polymer

### OMP-9

Inorganic fine particle OMP-9 was synthesized in the same manner as in Syntheses example 7 of OMP-7 except for changing BLENMER PME-100 to BLENMER PME-1000 shown below.

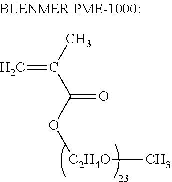

### 13. Syntheses Example of Inorganic Fine Particle Surface Modified with Low Molecular Organic Compound for Comparative Example

### LMP-1

Into a 100-ml 3-necked flask was charged 22.27 g of polyethylene glycol monomethyl ether (produced by Aldorich Corp., Mn: 550). While stirring the polyethylene glycol monomethyl ether with a mechanical stirrer, 10 g of 3-isocyanatopropyltriethyoxysilane (A-1310, produced by Union Carbide Corp.) was charged into the flask. After the charging of 3-isocyanatopropyltriethyoxysilane, 0.5 g of dibutyltin dilaurate (produced by Tokyo Chemical Industry Co., Ltd.) was added to the flask and the mixture was stirred for 24 hours at normal temperature. The content in the flask was separated into the ethanol solution and the precipitate by a centrifugal at 7,000 rpm for 30 minutes. The precipitate was dispersed in 400 ml of acetone using an ultrasonic disperser and after the dispersion the resulting mixture was separated again by a centrifugal. The operation of acetone washing was further repeated twice and the resulting precipitate was dried naturally to obtain 23 g of white powder.

### Examples 1 to 30 and Comparative Examples 1 to 2

### 1. Preparation of Lithographic Printing Plate Precursor

### (1) Preparation of Support

An aluminum plate (material: JIS A 1050) having a thickness of 0.3 mm was subjected to a degreasing treatment at 50° C. for 30 seconds using a 10% by weight aqueous sodium aluminate solution in order to remove rolling oil on the surface thereof and then grained the surface thereof using three nylon brushes embedded with bundles of nylon bristle having a diameter of 0.3 mm and an aqueous suspension (specific gravity: 1.1 g/cm³) of pumice having a median size of 25 μm, followed by thorough washing with water. The plate was subjected to etching by immersing in a 25% by weight aqueous sodium hydroxide solution of 45° C. for 9 seconds, washed with water, then immersed in a 20% by weight aqueous nitric acid solution at 60° C. for 20 seconds, and washed with water. The etching amount of the grained surface was about 3 g/m².

Then, using an alternating current of 60 Hz, an electrochemical roughening treatment was continuously carried out on the plate. The electrolytic solution used was a 1% by weight aqueous nitric acid solution (containing 0.5% by weight of aluminum ion) and the temperature of electrolytic solution was 50° C. The electrochemical roughening treatment was conducted using an alternating current source, which provides a rectangular alternating current having a trapezoidal waveform such that the time TP necessary for the current value to reach the peak from zero was 0.8 msec and the duty ratio was 1:1, and using a carbon electrode as a counter electrode. A ferrite was used as an auxiliary anode. The current density was 30 A/dm² in terms of the peak value of the electric current, and 5% of the electric current flowing from the electric source was divided to the auxiliary anode. The quantity of electricity in the nitric acid electrolysis was 175 C/dm² in terms of the quantity of electricity when the aluminum plate functioned as an anode. The plate was then washed with water by spraying.

The plate was further subjected to an electrochemical roughening treatment in the same manner as in the nitric acid electrolysis above using as an electrolytic solution, a 0.5% by weight aqueous hydrochloric acid solution (containing 0.5% by weight of aluminum ion) having temperature of 50° C. and under the condition that the quantity of electricity was 50 C/dm² in terms of the quantity of electricity when the aluminum plate functioned as an anode. The plate was then washed with water by spraying.

The plate was then subjected to an anodizing treatment using as an electrolytic solution, a 15% by weight aqueous sulfuric acid solution (containing 0.5% by weight of aluminum ion) at a current density of 15 A/dm² to form a direct current anodized film of 2.5 g/m², washed with water and dried.

Thereafter, in order to ensure the hydrophilicity of the non-image area, the plate was subjected to silicate treatment using a 2.5% by weight aqueous sodium silicate No. 3 solution at 70° C. for 12 seconds. The adhesion amount of Si was 10 mg/m². Subsequently, the plate was washed with water to obtain a support. The center line average roughness (Ra) of the support was measured using a stylus having a diameter of 2 μm and found to be 0.51 μm.

### (2) Formation of Undercoat Layer

Coating solution (1) for undercoat layer shown below was coated on the support so as to have a dry coating amount of 20 mg/m² to prepare a support having an undercoat layer for using the experiments described below.

### <Coating Solution (1) for Undercoat Layer>

| | |
|---|---|
| Compound (1) for undercoat layer having structure shown below | 0.18 g |
| Hydroxyethyliminodiacetic acid | 0.10 g |
| Methanol | 55.24 g |
| Water | 6.15 g |

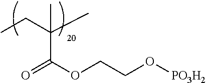

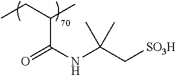

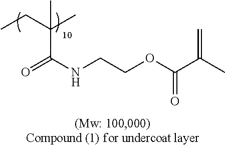

### (3) Formation of Image-Recording Layer

Each of Coating solutions (1) to (32) for image-recording layer having the composition shown below was coated on the undercoat layer described above by a bar and dried in an oven at 100° C. for 60 seconds to form an image-recording layer having a dry coating amount of 1.0 g/m².

Coating solutions (1) to (30) for image-recording layer were prepared by mixing Photosensitive solutions (1) to (30) shown below with Microgel solution (1) shown below just before the coating, followed by stirring, respectively. Coating solutions (31) to (32) for image-recording layer for the comparative examples were prepared by mixing Photosensitive solutions (31) to (32) shown below with Microgel solution (1) shown below just before the coating, followed by stirring, respectively.

### <Photosensitive Solutions (1) to (30)>

| | |
|---|---|
| Each of Inorganic fine particles surface | 0.200 g |
| modified with polymer (OMP-1) to (OMP-7) | |
| shown in Table 1 | |
| Binder polymer (1) or (2) having structure | 0.240 g |
| shown below | |
| Infrared absorbing agent (1) having | 0.030 g |
| structure shown below | |
| Radical polymerization initiator (1) having | 0.162 g |
| structure shown below | |
| Radical polymerizable compound (A): | 0.192 g |
| Tris(acryloyloxyethyl) isocyanurate (NK | |
| ESTER A-9300, produced by Shin-Nakamura | |
| Chemical Co., Ltd.) or | |
| Radical polymerizable compound (B): Monomer | 0.192 g |
| having ethyleneoxy group (*) | |
| Hydrophilic low molecular weight compound | 0.062 g |
| (Tris(2-hydroxyethyl) isocyanurate) | |
| Hydrophilic low molecular weight compound | 0.050 g |
| (1) having structure shown below | |
| Oil-sensitizing agent (Phosphonium compound | 0.055 g |
| (1) having structure shown below) | |
| Oil-sensitizing agent (Benzyl dimethyl | 0.018 g |
| octyl ammonium PF₆ salt | |
| Oil-sensitizing agent (Ammonium | 0.035 g |
| group-containing polymer having structure | |
| shown below (reduced specific viscosity: 44 cSt/g/ml) | |
| Fluorine-based surfactant (1) having | 0.008 g |
| structure shown below | |
| 2-Butanone | 1.091 g |
| 1-Methoxy-2-propanol | 8.609 g |

(*): A 40% by weight DMAC solution of monomer obtained by reacting DESMODUR N3200 (aliphatic polyisocyanate resin based on hexamethylene diisocyanate, produced by Bayer AG) with 2-amino-4-hydroxy-6-methylpyrimidine and polyethylene glycol monoacrylate (AE-400, produced by NOF Corp., Mn: 512)

### <Photosensitive Solution (31)>

| | |
|---|---|
| Binder polymer (1) having structure shown | 0.240 g |
| below | |
| Infrared absorbing agent (1) having | 0.030 g |
| structure shown below | |
| Radical polymerization initiator (1) having | 0.162 g |
| structure shown below | |
| Radical polymerizable compound (A): | 0.192 g |
| Tris(acryloyloxyethyl) isocyanurate (NK | |
| ESTER A-9300, produced by Shin-Nakamura | |
| Chemical Co., Ltd.) | |
| Hydrophilic low molecular weight compound | 0.062 g |
| (Tris(2-hydroxyethyl) isocyanurate) | |
| Hydrophilic low molecular weight compound | 0.050 g |
| (1) having structure shown below | |
| Oil-sensitizing agent (Phosphonium compound | 0.055 g |
| (1) having structure shown below) | |
| Oil-sensitizing agent (Benzyl dimethyl | 0.018 g |
| octyl ammonium PF₆ salt | |
| Oil-sensitizing agent (Ammonium | 0.035 g |
| group-containing polymer having structure | |
| shown below (reduced specific viscosity: 44 cSt/g/ml) | |
| Fluorine-based surfactant (1) having | 0.008 g |
| structure shown below | |
| 2-Butanone | 1.091 g |
| 1-Methoxy-2-propanol | 8.609 g |

### <Photosensitive Solution (32)>

| | |
|---|---|
| Inorganic fine particle surface modified | 0.200 g |
| with low molecular organic compound (LPM-1) | |
| Binder polymer (1) having structure shown | 0.240 g |
| below | |
| Infrared absorbing agent (1) having | 0.030 g |
| structure shown below | |
| Radical polymerization initiator (1) having | 0.162 g |
| structure shown below | |
| Radical polymerizable compound (A): | 0.192 g |
| Tris(acryloyloxyethyl) isocyanurate (NK | |
| ESTER A-9300, produced by Shin-Nakamura | |
| Chemical Co., Ltd.) | |
| Hydrophilic low molecular weight compound | 0.062 g |
| (Tris(2-hydroxyethyl) isocyanurate) | |
| Hydrophilic low molecular weight compound | 0.050 g |
| (1) having structure shown below | |
| Oil-sensitizing agent (Phosphonium compound | 0.055 g |
| (1) having structure shown below) | |
| Oil-sensitizing agent (Benzyl dimethyl | 0.018 g |
| octyl ammonium PF₆ salt | |
| Oil-sensitizing agent (Ammonium | 0.035 g |
| group-containing polymer having structure | |
| shown below (reduced specific viscosity: 44 cSt/g/ml) | |
| Fluorine-based surfactant (1) having | 0.008 g |
| structure shown below | |
| 2-Butanone | 1.091 g |
| 1-Methoxy-2-propanol | 8.609 g |

### <Microgel Solution (1)>

| | |
|---|---|
| Microgel (1) shown below | 2.640 g |
| Distilled water | 2.425 g |

The structures of Binder polymers (1) and (2), Infrared absorbing agent (1), Radical polymerization initiator (1), Phosphonium compound (1), Hydrophilic low molecular weight compound (1), Oil-sensitizing agent (ammonium group-containing polymer) and Fluorine-based surfactant (1) are shown below.

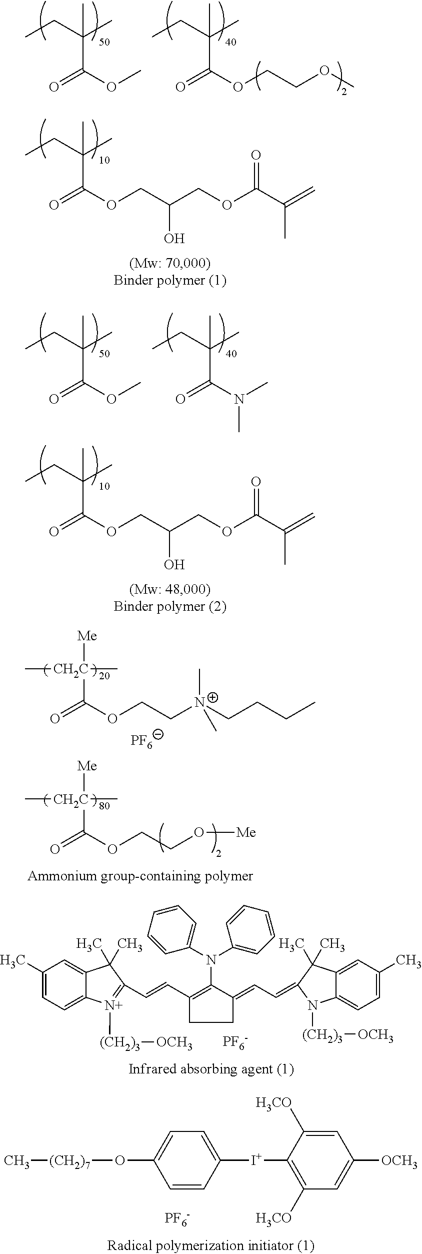

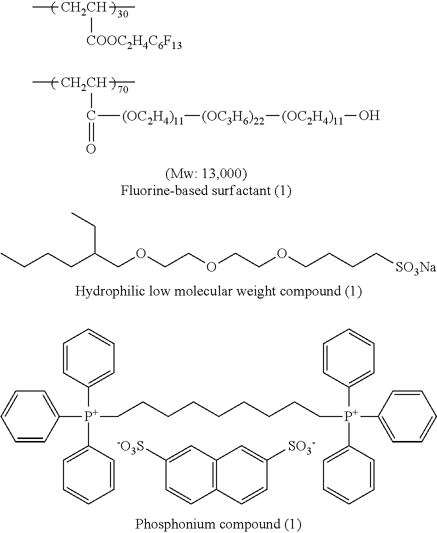

### <Preparation of Microgel (1)>

An oil phase component was prepared by dissolving 10 g of adduct of trimethylol propane and xylene diisocyanate (TAKENATE D-110N, produced by Mitsui Chemicals Polyurethanes, Inc.), 3.15 g of pentaerythritol triacrylate (SR444, produced by Nippon Kayaku Co., Ltd.) and 0.1 g of PIONIN A-41C (produced by Takemoto Oil & Fat Co., Ltd.) in 17 g of ethyl acetate. As an aqueous phase component, 40 g of a 4% by weight aqueous solution of PVA-205 was prepared. The oil phase component and the aqueous phase component were mixed and emulsified using a homogenizer at 12,000 rpm for 10 minutes. The resulting emulsion was added to 25 g of distilled water and stirred at room temperature for 30 minutes and then at 50° C. for 3 hours. The microgel liquid thus-obtained was diluted using distilled water so as to have the solid concentration of 15% by weight to prepare Microgel (1). The average particle size of the microgel was measured by a light scattering method and found to be 0.2 μm.

### (4) Formation of Protective Layer

Coating solution (1) for protective layer having the composition shown below was coated on the image-recording layer described above by a bar and dried in an oven at 120° C. for 60 seconds to form a protective layer having a dry coating amount of 0.15 g/m², thereby preparing lithographic printing plate precursors for Examples 1 to 30 and lithographic printing plate precursors for Comparative Examples 1 and 2, respectively.

### <Coating Solution (1) for Protective Layer>

| | |
|---|---|
| Dispersion of inorganic stratiform compound | 1.50 g |
| (1) shown below | |
| Aqueous 6% by weight solution of polyvinyl | 0.55 g |
| alcohol (CKS 50, sulfonic acid-modified, | |
| saponification degree: 99% by mole or more, | |
| polymerization degree: 300, produced by | |
| Nippon Synthetic Chemical Industry Co., | |
| Ltd.) | |
| Aqueous 6% by weight solution of polyvinyl | 0.18 g |
| alcohol (PVA-405, saponification degree: | |
| 81.5% by mole, polymerization degree: 500, | |
| produced by Kuraray Co., Ltd.) | |
| Aqueous 6% by weight solution of surfactant | 0.14 g |
| (Emalex 710, produced by Nihon Emulsion Co., | |
| Ltd.) | |
| Ion-exchanged water | 2.68 g |

### <Preparation of Dispersion of Inorganic Stratiform Compound (1)>

To 193.6 g of ion-exchanged water was added 6.4 g of synthetic mica (SOMASIF ME-100, produced by CO—OP Chemical Co., Ltd.) and the mixture was dispersed using a homogenizer until an average particle size (according to a laser scattering method) became 3 μm to prepare Dispersion of inorganic stratiform compound (1). The aspect ratio of the inorganic particle thus-dispersed was 200 or more.

### 2. Evaluation of Lithographic Printing Plate Precursor

As for the lithographic printing plate precursors obtained above, (1) stability of coating solution for image-recording layer, (2) on-press development property and (3) printing durability were evaluated as shown below.

### (1) Stability of Coating Solution for Image-Recording Layer

Time-lapse stability of each of Coating solutions (1) to (32) for image-recording layer was evaluated. Specifically, each of Coating solutions (1) to (32) for image-recording layer was charged into a cylindrical measuring cylinder having a diameter of 1.5 cm in an amount of 100 ml. The measuring cylinder was sealed to prevent evaporation and allowed to stand in circumstances of 25° C. A number of days which the precipitate of inorganic fine particle was not yet recognized was visually observed day by day for 7 days.

### (2) On-Press Development Property

Each of the lithographic printing plate precursors thus-obtained was exposed by LUXEL PLATESETTER T-6000III equipped with an infrared semiconductor laser, produced by Fujifilm Corp. under the conditions of a rotational number of an external drum of 1,000 rpm, laser output of 70% and resolution of 2,400 dpi. The exposed image contained a solid image and a 50% halftone dot chart of a 20 μm-dot FM screen.

The exposed lithographic printing plate precursor was mounted without undergoing development processing on a plate cylinder of a printing machine (LITHRONE 26, produced by Komori Corp.). Using dampening water (ECOLITY-2 (produced by Fujifilm Corp.)/tap water=2/98 (volume ratio)) and VALUES-G (N) Black Ink (produced by Dainippon Ink & Chemicals, Inc.), the dampening water and ink were supplied according to the standard automatic printing start method of LITHRONE 26 to conduct printing on 100 sheets of TOKUBISHI ART PAPER (76.5 kg) at a printing speed of 10,000 sheets per hour.

A number of the printing papers required until the on-press development of the unexposed area of the image-recording layer on the printing machine was completed to reach a state where the ink was not transferred to the printing paper in the non-image area was measured to evaluate the on-press development property. The results obtained are shown in Table 1.

### (3) Printing Durability

After performing the evaluation for the on-press development property described above, the printing was continued. As the increase in a number of printing papers, the image-recording layer was gradually abraded to cause decrease in the ink density on the printing paper. A number of the printing papers wherein a value obtained by measuring a halftone dot area rate of the 50% halftone dot of FM screen on the printing paper using a Gretag densitometer decreased by 5% from the value measured on the 100^{th} paper of the printing was determined to evaluate the printing durability. The results obtained are shown in Table 1.

TABLE 1

| | Photosensitive | Inorganic Fine | | | On-Press | Stability of | |
|---|---|---|---|---|---|---|---|
| | Solution for | Particle Surface | | Radical | Development | Coating Solution | Printing |
| | Image-Recording | Modified with | Binder | Polymerizable | Property | for Image- | Durability |
| | Layer | Polymer | Polymer | Compound | (sheets) | Recording Layer | (×10⁴ sheets) |
| Example 1 | (1) | OMP-1 | (1) | (A) | 20 | 7 days or more | 22 |
| Example 2 | (2) | OMP-2 | (1) | (A) | 25 | 7 days or more | 20 |
| Example 3 | (3) | OMP-3 | (1) | (A) | 25 | 6 days | 25 |
| Example 4 | (4) | OMP-4 | (1) | (A) | 30 | 5 days | 20 |
| Example 5 | (5) | OMP-5 | (1) | (A) | 25 | 5 days | 20 |
| Example 6 | (6) | OMP-6 | (1) | (A) | 20 | 6 days | 22 |
| Example 7 | (7) | OMP-7 | (1) | (A) | 25 | 5 days | 22 |
| Example 8 | (8) | OMP-8 | (1) | (A) | 25 | 5 days | 20 |
| Example 9 | (9) | OMP-9 | (1) | (A) | 20 | 6 days | 20 |
| Example 10 | (10) | OMP-1 | (2) | (A) | 25 | 7 days or more | 22 |
| Example 11 | (11) | OMP-2 | (2) | (A) | 30 | 7 days or more | 22 |
| Example 12 | (12) | OMP-3 | (2) | (A) | 30 | 6 days | 27 |
| Example 13 | (13) | OMP-4 | (2) | (A) | 35 | 5 days | 22 |
| Example 14 | (14) | OMP-5 | (2) | (A) | 30 | 5 days | 22 |
| Example 15 | (15) | OMP-6 | (2) | (A) | 25 | 6 days | 24 |
| Example 16 | (16) | OMP-1 | (1) | (B) | 15 | 7 days or more | 20 |
| Example 17 | (17) | OMP-2 | (1) | (B) | 20 | 7 days or more | 20 |
| Example 18 | (18) | OMP-3 | (1) | (B) | 20 | 6 days | 25 |
| Example 19 | (19) | OMP-4 | (1) | (B) | 25 | 5 days | 20 |
| Example 20 | (20) | OMP-5 | (1) | (B) | 20 | 5 days | 20 |
| Example 21 | (21) | OMP-6 | (1) | (B) | 15 | 6 days | 22 |
| Example 22 | (22) | OMP-7 | (1) | (B) | 20 | 5 days | 20 |
| Example 23 | (23) | OMP-8 | (1) | (B) | 20 | 5 days | 18 |
| Example 24 | (24) | OMP-9 | (1) | (B) | 15 | 6 days | 18 |
| Example 25 | (25) | OMP-1 | (2) | (B) | 20 | 7 days or more | 22 |
| Example 26 | (26) | OMP-2 | (2) | (B) | 25 | 7 days or more | 22 |
| Example 27 | (27) | OMP-3 | (2) | (B) | 25 | 6 days | 27 |
| Example 28 | (28) | OMP-4 | (2) | (B) | 30 | 5 days | 22 |
| Example 29 | (29) | OMP-5 | (2) | (B) | 25 | 5 days | 22 |
| Example 30 | (30) | OMP-6 | (2) | (B) | 20 | 6 days | 24 |
| Comparative | (31) | None | (1) | (A) | 45 | 7 days or more | 15 |
| Example 1 | | | | | | | |
| Comparative | (32) | LMP-1 | (1) | (A) | 45 | 3 days | 15 |
| Example 2 | | | | | | | |

As is apparent from the results shown in Table 1, the lithographic printing plate precursor which is excellent in the on-press development property and printing durability and is excellent in the stability of the coating solution for image-recording layer can be obtained according to the present invention.

What is claimed is:

1. A lithographic printing plate precursor comprising:
an aluminum support subjected to a surface roughening treatment; and
an image-recording layer which comprises an infrared absorbing agent, a radical polymerization initiator, a radical polymerizable compound and an inorganic particle which has, on a surface of the inorganic particle, an acrylic polymer as a graft chain and an unexposed area of which is capable of being removed with at least one of oily ink and dampening water.

2. The lithographic printing plate precursor as claimed in claim 1, wherein the graft chain is represented by the following formula (A):
-L₁-S—P₁ (A)
wherein L₁ represents a connecting chain covalently bonded to the inorganic particle, and P₁ represents an acrylic polymer chain.

3. The lithographic printing plate precursor as claimed in claim 1, wherein a surface of the inorganic particle is modified with the graft chain by a silane coupling reaction.

4. The lithographic printing plate precursor as claimed in claim 1, wherein the graft chain has a repeating unit represented by the following formula (B): 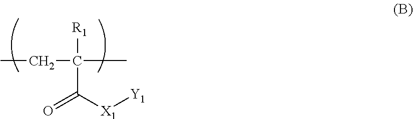
wherein R₁ represents a hydrogen atom or a methyl group, X₁ represents an oxygen atom, —NH— or a single bond, Y₁ represents a hydrogen atom, a polyalkyleneoxy group, an alkyl group having from 1 to 4 carbon atoms, —N(R₂)(R₃) or an alkyl or aryl group having at least one group selected from —N(R₂)(R₃), —NHCOR₂, —COOR₂, —OR₂, —CN, —SO₃H and a salt thereof, R₂ and R₃ each independently represents a hydrogen atom or an alkyl group having from 1 to 12 carbon atoms or R₂ and R₃ may be combined with each other to form a ring, and a number of the repeating units is from 10 to 1,000.

5. The lithographic printing plate precursor as claimed in claim 4, wherein X₁ represents an oxygen atom or —NH—, and Y₁ represents a polyethyleneoxy group.

6. The lithographic printing plate precursor as claimed in claim 5, wherein the graft chin has a repeating unit represented by the following formula (C): 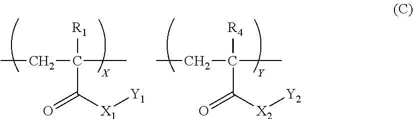
wherein Y₁ represents a polyethyleneoxy group, Y₂ represents a substituent having an ethylenically unsaturated group, X₁ and X₂ each independently represents an oxygen atom or —NH—, R₁ and R₄ each independently represents a hydrogen atom or a methyl group, X and Y each represents a copolymerization molar ratio of the repeating unit, X is from 10 to 90 and Y is from 5 to 50.

7. The lithographic printing plate precursor as claimed in claim 1, wherein the inorganic particle is a silica particle.

8. The lithographic printing plate precursor as claimed in claim 7, wherein the silica particle has an average particle size of from 20 to 500 nm.

9. The lithographic printing plate precursor as claimed in claim 1, wherein the inorganic particle is an inorganic stratiform compound.

10. The lithographic printing plate precursor as claimed in claim 1, wherein the image-recording layer further comprises a polymer compound having a polyalkyleneoxy group in a side chain.

11. The lithographic printing plate precursor as claimed in claim 1, wherein the radical polymerizable compound in the image-recording layer has a polyalkyleneoxy group.

12. A plate making method comprising:
imagewise exposing the lithographic printing plate precursor as claimed in claim 1, and
removing an exposed area of the image-recording layer with at least one of oily ink and dampening water in a state where the exposed lithographic printing plate precursor is mounted on a printing machine,
wherein a development process is not conducted between the exposing and the removing.
